(19) United States
(12) Patent Application Publication
(10) Pub. No.: US 2024/0235521 A1
(43) Pub. Date: Jul. 11, 2024

(54) ACOUSTIC WAVE DEVICE AND METHOD FOR MANUFACTURING ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Kazunori INOUE, Nagaokakyo-shi (JP)

(21) Appl. No.: 18/611,815

(22) Filed: Mar. 21, 2024

Related U.S. Application Data
(63) Continuation of application No. PCT/JP2022/036781, filed on Sep. 30, 2022.
(60) Provisional application No. 63/250,547, filed on Sep. 30, 2021.

(51) Int. Cl. H03H 9/10; H03H 3/02; H03H 9/02; H03H 9/05; H03H 9/13; H03H 9/17

(52) U.S. Cl. CPC H03H 9/105; H03H 3/02; H03H 9/02031; H03H 9/02157; H03H 9/02228; H03H 9/0523; H03H 9/132; H03H 9/173; H03H 9/176; H03H 2003/021

(57) ABSTRACT

An acoustic wave device includes an acoustic wave element including a support including a support substrate having a thickness in a first direction, a piezoelectric layer laminated on the support portion and including a first main surface and a second main surface opposite to the first main surface in the first direction, and a functional electrode on at least one of the first main surface and the second main surface of the piezoelectric layer, and a package to house the acoustic wave element. The support portion includes a first space on a piezoelectric layer side at a position where the first space at least partially overlaps the functional electrode in a plan view in the first direction, the package includes a second space outside the first space, and the piezoelectric layer includes a through-hole communicating with the first space and the second space.

### CROSS REFERENCE TO RELATED APPLICATIONS

This application claims the benefit of priority to Provisional Application No. 63/250,547, filed on Sep. 30, 2021, and is a Continuation Application of PCT Application No. PCT/JP2022/036781, filed on Sep. 30, 2022. The entire contents of each application are hereby incorporated herein by reference.

### BACKGROUND OF THE INVENTION

### 1. Field of the Invention

The present disclosure relates to acoustic wave devices and methods for manufacturing acoustic wave devices.

### 2. Description of the Related Art

Japanese Unexamined Patent Application Publication No. 2012-257019 describes an acoustic wave device.

The acoustic wave device described in Japanese Unexamined Patent Application Publication No. 2012-257019 may have a space therein. In this case, a piezoelectric layer may be damaged due to an air pressure difference between the space and the outside thereof.

### SUMMARY OF THE INVENTION

Example embodiments of the present invention are able to reduce or prevent damage to the piezoelectric layer.

An acoustic wave device according to an example embodiment of the present invention includes an acoustic wave element including a support including a support substrate having a thickness in a first direction, a piezoelectric layer laminated on the support and including a first main surface and a second main surface opposite to the first main surface in the first direction, and a functional electrode on at least one of the first main surface and the second main surface of the piezoelectric layer, and a package to house the acoustic wave element. The support includes a first space on a piezoelectric layer side at a position where the first space at least partially overlaps the functional electrode in a plan view in the first direction, the package includes a second space outside the first space, the piezoelectric layer includes a through-hole communicating with the first space and the second space, and the first space, the second space, and the outside of the package communicate with each other through at least one path.

An acoustic wave device according to an example embodiment of the present invention includes an acoustic wave element including a support including a support substrate having a thickness in a first direction, a piezoelectric layer laminated on the support portion and including a first main surface and a second main surface opposite to the first main surface in the first direction, and a functional electrode on at least one of the first main surface and the second main surface of the piezoelectric layer, and a package to house the acoustic wave element. The support includes a first space on a piezoelectric layer side at a position where the first space at least partially overlaps the functional electrode in a plan view in the first direction, the package includes a second space outside the first space, the piezoelectric layer includes a through-hole communicating with the first space and the second space, and the first space, the second space, and the outside of the package have the same air pressure.

An acoustic wave device according to an example embodiment of the present invention includes a support including a support substrate having a thickness in a first direction, a piezoelectric layer laminated on the support and including a first main surface and a second main surface opposite to the first main surface in the first direction, a functional electrode on at least one of the first main surface and the second main surface of the piezoelectric layer, a support frame on the piezoelectric layer in the first direction, and a cover on the support frame in the first direction. The support includes a first space on a piezoelectric layer side at a position where the first space at least partially overlaps the functional electrode in a plan view in the first direction, the support frame includes a second space, the piezoelectric layer includes a through-hole through which the first space and the second space communicate with each other, and the first space, the second space, and the outside of the cover communicate with each other through at least one path.

An acoustic wave device according to an example embodiment of the present invention includes a support including a support substrate having a thickness in a first direction, a piezoelectric layer laminated on the support portion and including a first main surface and a second main surface opposite to the first main surface in the first direction, a functional electrode on at least one of the first main surface and the second main surface of the piezoelectric layer, a support frame on the piezoelectric layer in the first direction, and a cover provided on the support frame in the first direction. The support includes a first space on a piezoelectric layer side at a position where the first space at least partially overlaps the functional electrode in a plan view in the first direction, the support frame includes a second space, the piezoelectric layer includes a through-hole through which the first space and the second space communicate with each other, and the first space, the second space, and the outside of the cover have the same air pressure.

A method for manufacturing an acoustic wave device according to an example embodiment of the present invention includes a sacrificial layer forming step of forming a sacrificial layer on a portion of one of a pair of main surfaces of a piezoelectric layer including the pair of main surfaces opposite to each other in a thickness direction, an intermediate layer forming step of forming an intermediate layer on the one main surface of the piezoelectric layer and the sacrificial layer, a bonding step of bonding the piezoelectric layer to a support substrate with the intermediate layer interposed therebetween, an electrode forming step of forming an electrode on at least one of the pair of main surfaces of the piezoelectric layer, a through-hole forming step of forming a through-hole in the piezoelectric layer, and a sacrificial layer removal step of removing the sacrificial layer.

A method for manufacturing an acoustic wave device according to an example embodiment of the present invention includes an intermediate layer forming step of forming an intermediate layer on a support substrate, a piezoelectric layer forming step of forming a piezoelectric layer on the intermediate layer, an electrode forming step of forming an electrode on the piezoelectric layer, a through-hole forming step of forming a through-hole in the piezoelectric layer and the intermediate layer, a first etching step of forming a space in a portion of the support substrate, and a second etching step of etching the intermediate layer exposed to the space.

According to example embodiments of the present invention, damage to a piezoelectric layer is able to be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to a first example embodiment of the present invention.

FIG. 1B is a plan view of an electrode structure according to the first example embodiment of the present invention.

FIG. 2 is a sectional view of the acoustic wave device in FIG. 1A taken along line II-II.

FIG. 3A is a schematic sectional view illustrating a Lamb wave propagating through a piezoelectric layer of a comparative example.

FIG. 3B is a schematic sectional view illustrating a bulk wave in a first-order thickness-shear mode propagating through a piezoelectric layer of the first example embodiment of the present invention.

FIG. 4 is a schematic sectional view illustrating an amplitude direction of a bulk wave in a first-order thickness-shear mode propagating through the piezoelectric layer of the first example embodiment of the present invention.

FIG. 5 is a graph illustrating an example of resonance characteristics of the acoustic wave device of the first example embodiment of the present invention.

FIG. 6 is a graph illustrating a relationship between d/2p and a fractional bandwidth as a resonator in the acoustic wave device of the first example embodiment of the present invention, when a center-to-center distance of adjacent electrodes or an average thereof is represented by p and a thickness of the piezoelectric layer is represented by d.

FIG. 7 is a plan view illustrating an example in which a pair of electrodes is provided in the acoustic wave device of the first example embodiment of the present invention.

FIG. 8 is a graph illustrating an example of resonance characteristics of the acoustic wave device of the first example embodiment of the present invention.

FIG. 9 is a diagram illustrating a relationship between a fractional bandwidth, when a large number of acoustic wave resonators are configured, and a phase rotation amount of an impedance of a spurious component normalized by 180 degrees as a spurious component level, in the acoustic wave device of the first example embodiment of the present invention.

FIG. 10 is a diagram illustrating a relationship between d/2p, a metallization ratio MR, and a fractional bandwidth.

FIG. 11 is a diagram illustrating a map of a fractional bandwidth relative to Euler angles (0°, θ, ψ) of LiNbO₃ when d/p is made as close to 0 as possible.

FIG. 12 is a partially cutaway perspective view illustrating the acoustic wave device according to an example embodiment of the present invention.

FIG. 13 is a sectional view illustrating an example of the acoustic wave device according to the first embodiment of the present invention.

FIG. 14 is a schematic sectional view illustrating a sacrificial layer forming step in a method for manufacturing the acoustic wave device according to the first example embodiment of the present invention.

FIG. 15 is a schematic sectional view illustrating an intermediate layer forming step in the method for manufacturing the acoustic wave device according to the first example embodiment of the present invention.

FIG. 16 is a schematic sectional view illustrating a bonding step in the method for manufacturing the acoustic wave device according to the first example embodiment of the present invention.

FIG. 17 is a schematic sectional view illustrating a piezoelectric layer polishing step in the method for manufacturing the acoustic wave device according to the first example embodiment of the present invention.

FIG. 18 is a schematic sectional view illustrating an electrode forming step in the method for manufacturing the acoustic wave device according to the first example embodiment of the present invention.

FIG. 19 is a schematic sectional view illustrating a through-hole forming step in the method for manufacturing the acoustic wave device according to the first example embodiment of the present invention.

FIG. 20 is a schematic sectional view illustrating a sacrificial layer removal step in the method for manufacturing the acoustic wave device according to the first example embodiment of the present invention.

FIG. 21 is a plan view of an acoustic wave device according to a second example embodiment of the present invention.

FIG. 22 is a sectional view of the acoustic wave device in FIG. 21 taken along line XXII-XXII.

FIG. 23 is a plan view of part of the acoustic wave device according to the second example embodiment of the present invention.

FIG. 24 is a diagram illustrating a filler filling step in a method for manufacturing the acoustic wave device according to the second example embodiment of the present invention.

FIG. 25 is a diagram illustrating a support frame forming step in the method for manufacturing the acoustic wave device according to the second example embodiment of the present invention.

FIG. 26 is a diagram illustrating a filler etching step in the method for manufacturing the acoustic wave device according to the second example embodiment of the present invention.

FIG. 27 is a sectional view of an acoustic wave device according to a third example embodiment of the present invention.

FIG. 28 is a schematic sectional view illustrating an intermediate layer forming step in a method for manufacturing the acoustic wave device according to the third example embodiment of the present invention.

FIG. 29 is a schematic sectional view illustrating a bonding step in the method for manufacturing the acoustic wave device according to the third example embodiment of the present invention.

FIG. 30 is a schematic sectional view illustrating a piezoelectric layer polishing step in the method for manufacturing the acoustic wave device according to the third example embodiment of the present invention.

FIG. 31 is a schematic sectional view illustrating an electrode forming step in the method for manufacturing the acoustic wave device according to the third example embodiment of the present invention.

FIG. 32 is a schematic sectional view illustrating a through-hole forming step in the method for manufacturing the acoustic wave device according to the third example embodiment of the present invention.

FIG. 33 is a diagram illustrating a through-plug forming step in the method for manufacturing the acoustic wave device according to the third example embodiment of the present invention.

FIG. 34 is a schematic sectional view illustrating a first etching step in the method for manufacturing the acoustic wave device according to the third example embodiment of the present invention.

FIG. 35 is a schematic sectional view illustrating a second etching step in the method for manufacturing the acoustic wave device according to the third example embodiment of the present invention.

### DETAILED DESCRIPTION OF THE EXAMPLE EMBODIMENTS

Hereinafter, example embodiments of the present invention will be described in detail with reference to the drawings. The present disclosure is not limited to the example embodiments. Each example embodiment described in the present disclosure is merely an example, and in different example embodiments such as modifications in which partial replacement or combination of configurations is possible and the second and subsequent example embodiments, a description of matters common to the first example embodiment will be omitted, and only different points will be described. In particular, the same effect due to the same configuration will not be described in each example embodiment.

### First Example Embodiment

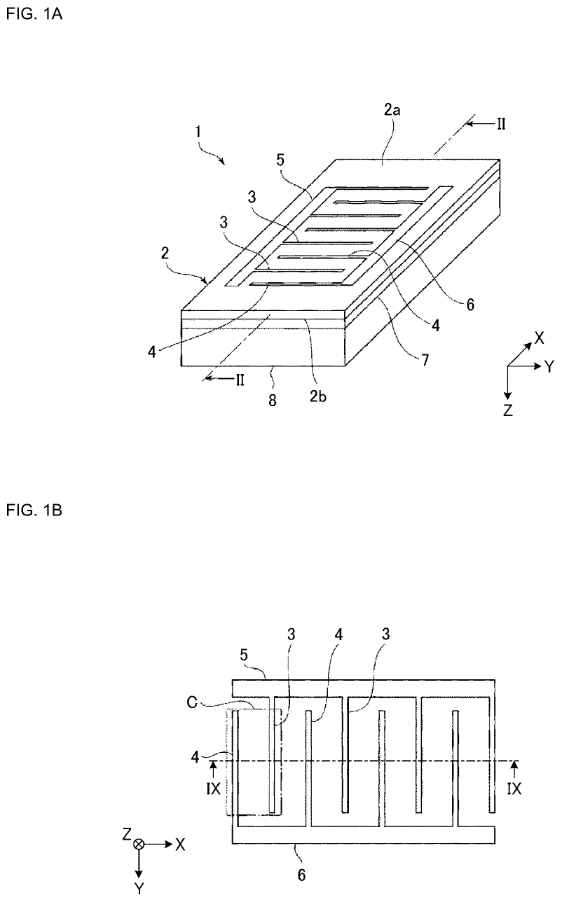

FIG. 1A is a perspective view of an acoustic wave device according to a first example embodiment of the present invention. FIG. 1B is a plan view of an electrode structure according to the first example embodiment.

An acoustic wave device 1 of the first example embodiment preferably includes a piezoelectric layer 2 made of, for example, LiNbO₃. The piezoelectric layer 2 may be made of, for example, LiTaO₃. A cut angle of LiNbO₃ or LiTaO₃ is Z-cut in the first example embodiment. The cut angle of LiNbO₃ or LiTaO₃ may be a rotated Y-cut or an X-cut. Preferably, Y-propagation and X-propagation about ±30° is preferred as a propagation orientation.

A thickness of the piezoelectric layer 2 is not particularly limited, but is preferably, for example, about 50 nm or more and about 1000 nm or less in order to effectively excite a first-order thickness-shear mode.

The piezoelectric layer 2 includes a first main surface 2a and a second main surface 2b opposite to each other in a Z-direction. Electrode fingers 3 and 4 are provided on the first main surface 2a.

The electrode finger 3 is an example of a “first electrode finger”, and the electrode finger 4 is an example of a “second electrode finger”. In FIGS. 1A and 1B, the plurality of electrode fingers 3 are the plurality of “first electrode fingers” coupled to a first busbar electrode 5. The plurality of electrode fingers 4 are the plurality of “second electrode fingers” coupled to a second busbar electrode 6. The plurality of electrode fingers 3 and the plurality of electrode fingers 4 are interdigitated with each other. Thus, an interdigital transducer (IDT) electrode including the electrode finger 3, the electrode finger 4, the first busbar electrode 5, and the second busbar electrode 6 is configured.

The electrode finger 3 and the electrode finger 4 each have a rectangular or substantially rectangular shape and include a length direction. The electrode finger 3 and the electrode finger 4 adjacent to the electrode finger 3 oppose each other in a direction orthogonal or substantially orthogonal to the length direction. The length direction of the electrode fingers 3 and 4 and the direction orthogonal or substantially orthogonal to the length direction of the electrode fingers 3 and 4 each are a direction intersecting a thickness direction of the piezoelectric layer 2. Therefore, it can be said that the electrode finger 3 and the electrode finger 4 adjacent to the electrode finger 3 oppose each other in the direction intersecting the thickness direction of the piezoelectric layer 2. In the following description, the thickness direction of the piezoelectric layer 2 may be referred to as the Z-direction (or a first direction), the length direction of the electrode fingers 3 and 4 may be referred to as a Y-direction (or a second direction), and a direction orthogonal to a length direction of the electrode fingers 3 and 4 may be referred to as an X-direction (or a third direction).

The length direction of the electrode fingers 3 and 4 may be exchanged with the direction orthogonal or substantially orthogonal to the length direction of the electrode fingers 3 and 4 illustrated in FIGS. 1A and 1B. That is, in FIGS. 1A and 1B, the electrode fingers 3 and 4 may extend in a direction in which the first busbar electrode 5 and the second busbar electrode 6 extend. In that case, the first busbar electrode 5 and the second busbar electrode 6 extend in a direction in which the electrode fingers 3 and 4 extend in FIGS. 1A and 1B. A plurality of structures, in which the electrode finger 3 coupled to one electric potential and the electrode finger 4 coupled to the other electric potential adjacent to each other make a pair, are provided in the direction orthogonal to the length direction of the electrode fingers 3 and 4.

Here, the electrode finger 3 and the electrode finger 4 being adjacent to each other does not mean that the electrode finger 3 and the electrode finger 4 are in direct contact with each other, and instead means that the electrode finger 3 and the electrode finger 4 are arranged with a gap therebetween. When the electrode finger 3 and the electrode finger 4 are adjacent to each other, no electrode, coupled to a hot electrode or a ground electrode including other electrode finger 3 or other electrode finger 4, is disposed between the electrode finger 3 and the electrode finger 4. The number of pairs is not necessarily an integer pair, and may be, for example, 1.5 pairs, 2.5 pairs, or the like.

A center-to-center distance between the electrode finger 3 and the electrode finger 4, that is, a pitch is preferably in a range of, for example, about 1 μm or more to about 10 μm or less.

The center-to-center distance between the electrode finger 3 and the electrode finger 4 is a distance connecting a center of a width measurement of the electrode finger 3 in the direction orthogonal to the length direction of the electrode finger 3 and a center of a width measurement of the electrode finger 4 in the direction orthogonal or substantially orthogonal to the length direction of the electrode finger 4.

When at least one of the electrode finger 3 and the electrode finger 4 is plural (when there are 1.5 or more electrode pairs in a case of defining electrode finger 3 and electrode finger 4 as an electrode pair), the center-to-center distance between the electrode finger 3 and the electrode finger 4 is an average value of the center-to-center distances between the adjacent electrode fingers 3 and 4 among the 1.5 or more pairs of electrode fingers 3 and 4.

The width of each of the electrode fingers 3 and 4, that is, the measurement of each of the electrode fingers 3 and 4 in a facing direction, is preferably in a range of, for example, about 150 nm or more to about 1000 nm or less. The center-to-center distance between the electrode finger 3 and the electrode finger 4 is a distance connecting the center of the measurement (width measurement) of the electrode finger 3 in the direction orthogonal to the length direction of the electrode finger 3 and the center of the measurement (width measurement) of the electrode finger 4 in the direction orthogonal or substantially orthogonal to the length direction of the electrode finger 4.

Further, in the first example embodiment, since the Z-cut piezoelectric layer is used, the direction orthogonal or substantially orthogonal to the length direction of the electrode fingers 3 and 4 is orthogonal or substantially orthogonal to a polarization direction of the piezoelectric layer 2. This is not the case when a piezoelectric material having another cut angle is used as the piezoelectric layer 2. Here, the term “orthogonal” is not limited to being strictly orthogonal, and may be substantially orthogonal (angle formed by the direction orthogonal to the length direction of the electrode fingers 3 and 4 and the polarization direction is about 90°±10°, for example).

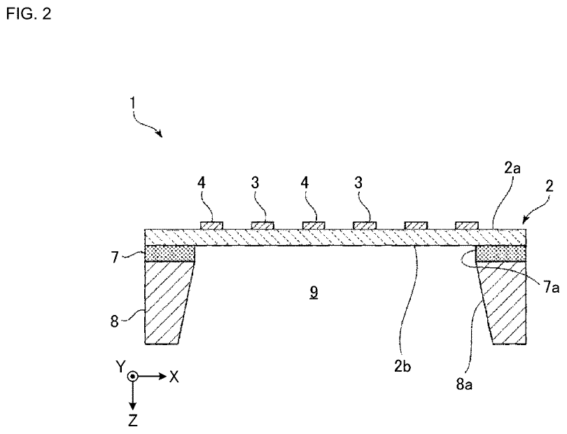

A support substrate 8 is laminated on the piezoelectric layer 2 on the second main surface 2b side with an intermediate layer 7 interposed therebetween. The intermediate layer 7 and the support substrate 8 each have a frame shape, and include a cavity 7a and a cavity 8a as illustrated in FIG. 2. Thus, a space (air gap) 9 is provided.

The space 9 is provided so as not to impede the vibration of an excitation region C of the piezoelectric layer 2. The support substrate 8 is laminated on the second main surface 2b with the intermediate layer 7 interposed therebetween at a position not overlapping a portion where at least one pair of the electrode fingers 3 and 4 is provided. The intermediate layer 7 may be omitted if so desired. The support substrate 8, therefore, may be laminated directly or indirectly on the second main surface 2b of the piezoelectric layer 2.

The intermediate layer 7 is made of silicon oxide. The intermediate layer 7 may be formed of an appropriate material such as, for example, silicon nitride or alumina, in addition to silicon oxide.

The support substrate 8 is made of, for example, Si. A plane orientation of a surface of Si on the piezoelectric layer 2 side may be, for example, (100), (110), or (111). High resistance Si having a resistivity of, for example, about 4 kΩ or more is preferable. The support substrate 8 may be made of an appropriate insulation material or semiconductor material. Examples of the material of the support substrate 8 include piezoelectric materials such as aluminum oxide, lithium tantalate, lithium niobate, and quartz; various ceramics such as alumina, magnesia, sapphire, silicon nitride, aluminum nitride, silicon carbide, zirconia, cordierite, mullite, steatite, and forsterite; dielectrics such as diamond and glass; and semiconductors such as gallium nitride.

The plurality of electrode fingers 3, the plurality of electrode fingers 4, the first busbar electrode 5, and the second busbar electrode 6 each are made of an appropriate metal or an alloy such as, for example, Al or an AlCu alloy. In the first example embodiment, the electrode fingers 3 and 4, the first busbar electrode 5, and the second busbar electrode 6 each preferably have a structure including an Al film that is laminated on a Ti film. An adhesion layer other than the Ti film may be used.

An alternating voltage is applied between the plurality of electrode fingers 3 and the plurality of electrode fingers 4 at the time of driving. More specifically, an alternating voltage is applied between the first busbar electrode 5 and the second busbar electrode 6. Thus, it becomes possible to obtain resonance characteristics using a bulk wave in a first-order thickness-shear mode excited in the piezoelectric layer 2.

In the acoustic wave device 1, when the thickness of the piezoelectric layer 2 is represented as d and the center-to-center distance between any adjacent electrode fingers 3 and 4 among the plurality of pairs of electrode fingers 3 and 4 is represented as p, d/p is preferably, for example, about 0.5 or less. As a result, a bulk wave of a first-order thickness-shear mode is effectively excited, and preferable resonance characteristics may be obtained. More preferably, for example, d/p is about 0.24 or less, and in this case, even more preferable resonance characteristics may be obtained.

When at least one of the electrode finger 3 and the electrode finger 4 is plural as in the first example embodiment, that is, when the electrode fingers 3 and 4 define 1.5 pairs or more in a case of defining the electrode fingers 3 and 4 as an electrode pair, the center-to-center distance p between the adjacent electrode fingers 3 and 4 is the average distance of the center-to-center distances between respective adjacent electrode fingers 3 and 4.

Since the acoustic wave device 1 of the first example embodiment has the above-described configuration, even when the number of pairs of the electrode fingers 3 and 4 is decreased in order to achieve the reduction in size, a Q factor is less likely to lower. This is because the resonator does not require a reflector on both sides and has a small propagation loss. A reflector is not required because a bulk wave of a first-order thickness-shear mode is used.

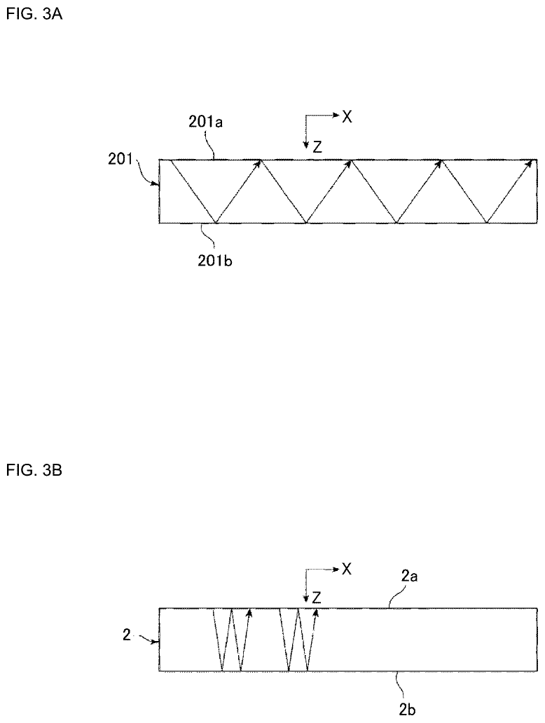

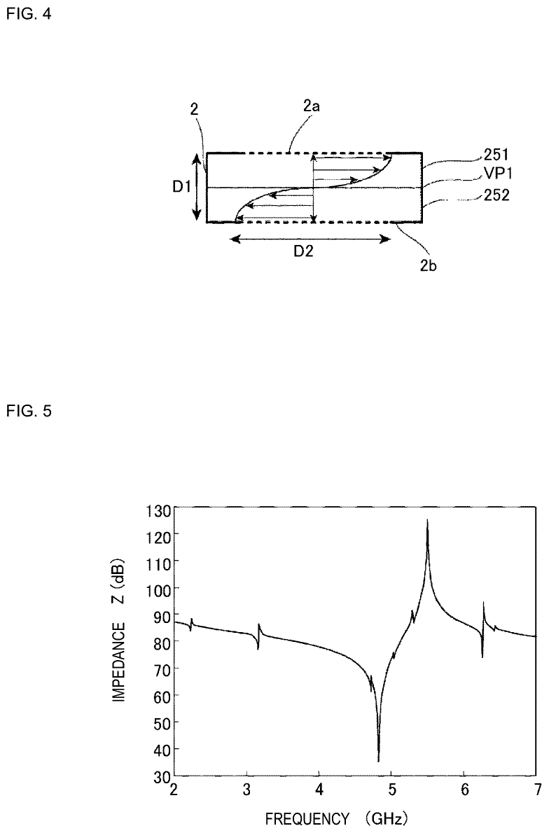

FIG. 3A is a schematic sectional view illustrating a Lamb wave propagating through a piezoelectric layer of a comparative example. FIG. 3B is a schematic sectional view illustrating a bulk wave in a first-order thickness-shear mode propagating through the piezoelectric layer of the first example embodiment. FIG. 4 is a schematic sectional view illustrating an amplitude direction of a bulk wave in a first-order thickness-shear mode propagating through the piezoelectric layer of the first example embodiment.

An acoustic wave device in FIG. 3A is the acoustic wave device as described in Japanese Unexamined Patent Application Publication No. 2012-257019, and a Lamb wave propagates through the piezoelectric layer. As illustrated in FIG. 3A, waves propagate in a piezoelectric layer 201 as indicated by arrows. The piezoelectric layer 201 includes a first main surface 201a and a second main surface 201b, and a thickness direction connecting the first main surface 201a and the second main surface 201b is the Z-direction. The X-direction is a direction in which the electrode fingers 3 and 4 of an IDT electrode are arranged. As illustrated in FIG. 3A, a Lamb wave propagates in the X-direction as illustrated in the figure. The piezoelectric layer 201 vibrates as a whole because of a plate wave, but the wave propagates in the X-direction, and thus reflectors are disposed on both sides to obtain resonance characteristics. As a result, a propagation loss of a wave occurs, and when the reduction in size is achieved, that is, when the number of pairs of the electrode fingers 3 and 4 is decreased, the Q factor lowers.

In contrast, as illustrated in FIG. 3B, in the acoustic wave device of the first example embodiment, displacement of vibration is in a thickness-shear direction. Thus, the wave propagates substantially in a direction connecting the first main surface 2a and the second main surface 2b of the piezoelectric layer 2, that is, in the Z-direction, and resonates. That is, the X-direction component of the wave is markedly smaller than the Z-direction component. Since the resonance characteristics are obtained by the propagation of the wave in the Z-direction, no reflector is required. Accordingly, a propagation loss, when the wave propagates to the reflector, does not occur. Therefore, even when the number of electrode pairs each defined by the electrode fingers 3 and 4 is decreased for further reduction in size, the Q factor is less likely to lower.

As illustrated in FIG. 4, amplitude directions of a bulk wave in a first-order thickness-shear mode have opposite directions in a first region 251 included in the excitation region C (see FIG. 1B) of the piezoelectric layer 2 and in a second region 252 included in the excitation region C. FIG. 4 schematically illustrates a bulk wave in a case that a voltage is applied between the electrode finger 3 and the electrode finger 4 such that the electrode finger 4 has a higher electric potential than that of the electrode finger 3. The first region 251 is a region of the excitation region C between a virtual plane VP1, which is orthogonal to the thickness direction of the piezoelectric layer 2 and divides the piezoelectric layer 2 into two, and the first main surface 2a. The second region 252 is a region of the excitation region C between the virtual plane VP1 and the second main surface 2b.

In the acoustic wave device 1, at least one pair of electrodes defined by the electrode fingers 3 and 4 is provided. However, since a wave does not propagate in the X-direction, the number of pairs of electrodes defined by the electrode fingers 3 and 4 is not necessarily plural. That is, it is sufficient that at least one pair of electrodes is provided.

For example, the electrode finger 3 is an electrode coupled to a hot electric potential, and the electrode finger 4 is an electrode coupled to a ground electric potential. However, the electrode finger 3 may be coupled to the ground electric potential, and the electrode finger 4 may be coupled to the hot electric potential. In the first example embodiment, as described above, in at least one pair of electrodes, the electrodes are coupled to the hot electric potential and the ground electric potential, and no floating electrode is provided.

FIG. 5 is a graph illustrating an example of resonance characteristics of the acoustic wave device of the first example embodiment. The design parameters of the acoustic wave device 1 having the resonance characteristics illustrated in FIG. 5 are as follows.

Piezoelectric layer 2: LiNbO₃ of Euler angles (0°, 0°, 90°)
Thickness of piezoelectric layer 2: about 400 nm
Length of excitation region C (see FIG. 1B): about 40 μm
Number of pairs of electrodes of electrode fingers 3 and 4: 21 pairs
Center-to-center distance (pitch) between electrode finger 3 and electrode finger 4: about 3 μm
Width of each of the electrode fingers 3 and 4: about 500 nm
d/p: about 0.133
Intermediate layer 7: silicon oxide film of about 1 μm thickness
Support substrate 8: Si

The excitation region C (see FIG. 1B) is a region where the electrode fingers 3 and 4 overlap each other when viewed in the X-direction orthogonal or substantially orthogonal to the length direction of the electrode fingers 3 and 4. The length of the excitation region C is a measurement of the excitation region C in the length direction of the electrode fingers 3 and 4.

In the first example embodiment, a distance between the electrode finger 3 and the electrode finger 4 defining an electrode pair is all equal or substantially equal in the plurality of pairs. That is, the electrode fingers 3 and the electrode fingers 4 are arranged at an equal or substantially equal pitch.

As is clear from FIG. 5, although the reflector is not provided, good resonance characteristics with a fractional bandwidth of about 12.5% is obtained.

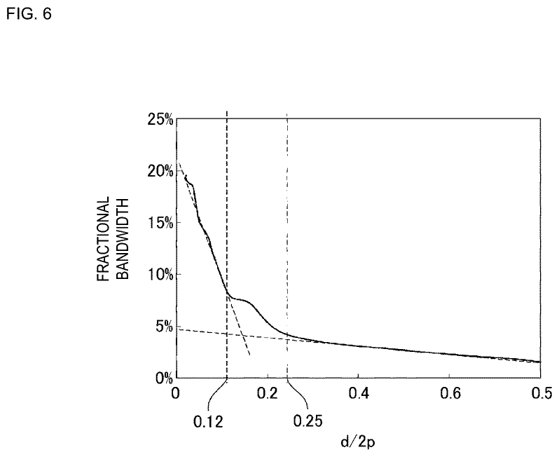

When the thickness of the piezoelectric layer 2 is represented as d and the center-to-center distance between the electrode fingers 3 and 4 is represented as p, for example, d/p is about 0.5 or less, and more preferably about 0.24 or less in the first example embodiment. This will be described with reference to FIG. 6.

A plurality of acoustic wave devices are obtained in the same or substantially the same manner as the acoustic wave device having the resonance characteristics illustrated in FIG. 5, but d/2p is changed. FIG. 6 is a graph illustrating a relationship between d/2p and a fractional bandwidth as a resonator, in which a center-to-center distance or an average center-to-center distance between adjacent electrodes is represented as p and an average thickness of the piezoelectric layer 2 is represented as d, in the acoustic wave device of the first example embodiment.

As illustrated in FIG. 6, when d/2p exceeds about 0.25, that is, when d/p>about 0.5, the fractional bandwidth is less than about 5% even if d/p is adjusted. In contrast, when d/2p≤about 0.25, that is, d/p≤about 0.5, the fractional bandwidth may be about 5% or more by changing d/p within the range, that is, a resonator having a high coupling coefficient may be configured. When d/2p is about 0.12 or less, that is, when d/p is about 0.24 or less, the fractional bandwidth may be increased to about 7% or more. In addition, when d/p is adjusted within the range, a resonator having a still wider fractional bandwidth may be obtained, and a resonator having a still higher coupling coefficient may be realized. Accordingly, it is understood that a resonator, having a high coupling coefficient using the above-described bulk wave of a first-order thickness-shear mode, may be configured by making d/p about 0.5 or less, for example.

The at least one pair of electrodes may be one pair, and in a case of one pair of electrodes, the above-described p is the center-to-center distance between the adjacent electrode fingers 3 and 4. In a case of 1.5 or more pairs of electrodes, the average distance between the centers of the adjacent electrode fingers 3 and 4 is set to p.

Further, when the piezoelectric layer 2 has variation in thickness, an average value of the thicknesses is set to the thickness d of the piezoelectric layer 2 as well.

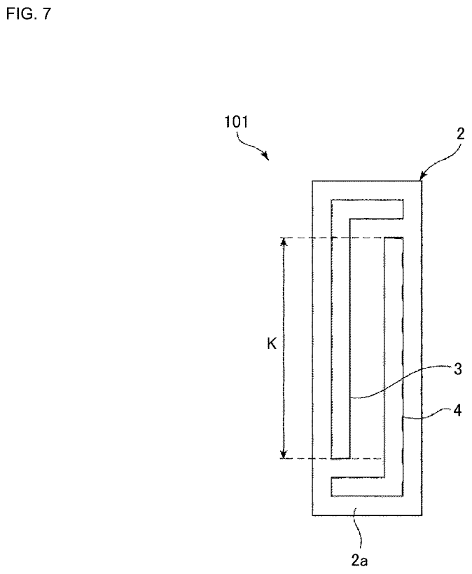

FIG. 7 is a plan view illustrating an example in which a pair of electrodes is provided in the acoustic wave device of the first example embodiment. In an acoustic wave device 101, a pair of electrodes including the electrode fingers 3 and 4 is provided on the first main surface 2a of the piezoelectric layer 2. In FIG. 7, K is an overlap width. As described above, in the acoustic wave device according to the present disclosure, the number of pairs of electrodes may be one. Even in this case, when d/p above is about 0.5 or less, a bulk wave of a first-order thickness-shear mode may effectively be excited.

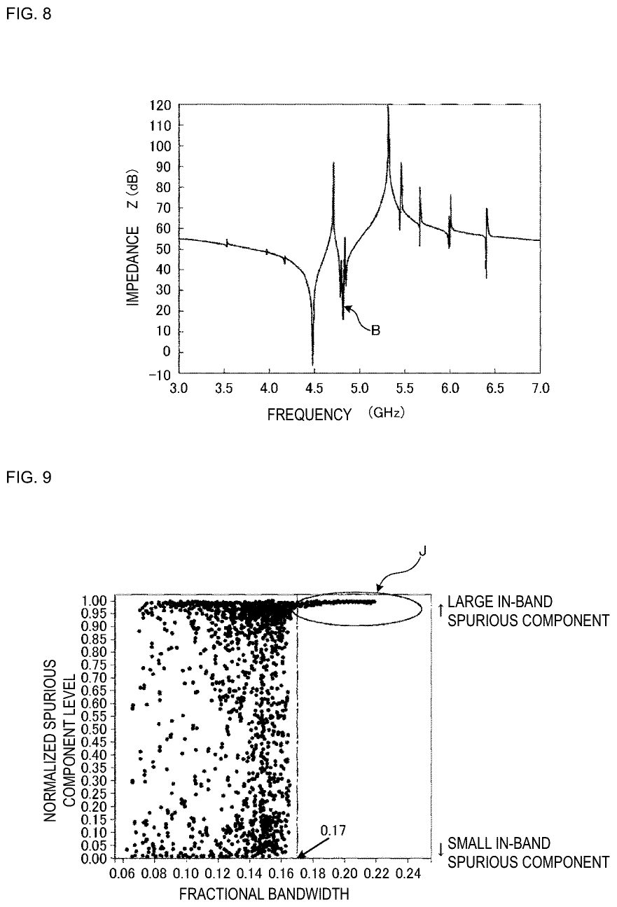

In the acoustic wave device 1, it is preferable that a metallization ratio MR of the adjacent electrode fingers 3 and 4 to the excitation region C satisfies MR≤about 1.75 (d/p)+0.075. The excitation region C is a region where any adjacent electrode fingers 3 and 4, in the plurality of the electrode fingers 3 and 4, overlap each other when viewed in a direction in which the electrode finger 3 and the electrode finger 4 oppose each other. In that case, a spurious component may effectively be reduced. This will be described with reference to FIG. 8 and FIG. 9.

FIG. 8 is a graph illustrating an example of resonance characteristics of the acoustic wave device of the first example embodiment. A spurious response indicated by an arrow B appears between a resonant frequency and an anti-resonant frequency. Note that d/p is set to about 0.08 and Euler angles of LiNbO₃ were (0°, 0°, 90°). The metallization ratio MR is set to about 0.35.

The metallization ratio MR will be explained with reference to FIG. 1B. In the electrode structure illustrated in FIG. 1B, when attention is focused one pair of the electrode fingers 3 and 4, only the one pair of the electrode fingers 3 and 4 is assumed to be provided. In this case, a portion surrounded by a dashed-and-dotted line is the excitation region C. The excitation region C is a region including regions described below when the electrode fingers 3 and 4 are viewed in the direction orthogonal to the length direction of the electrode fingers 3 and 4, that is, the facing direction. The regions are a region of the electrode finger 3 overlapping the electrode finger 4, a region of the electrode finger 4 overlapping the electrode finger 3, and a region where the electrode finger 3 and the electrode finger 4 overlap each other in a region between the electrode finger 3 and the electrode finger 4. The area of the electrode fingers 3 and 4 in the excitation region C relative to the area of the excitation region C is the metallization ratio MR. That is, the metallization ratio MR is a ratio of the area of the metallization portion to the area of the excitation region C.

When a plurality of pairs of the electrode fingers 3 and 4 are provided, MR is a ratio of the metallization portion included in the entire excitation region C to the total area of the excitation region C.

FIG. 9 is a diagram illustrating a relationship between a fractional bandwidth and a phase rotation amount of the impedance of a spurious component normalized by about 180 degrees as a spurious component level, when a large number of acoustic wave resonators are configured in the acoustic wave device of the first example embodiment. The fractional bandwidth is adjusted by variously changing a film thickness of the piezoelectric layer 2 and the measurements of the electrode fingers 3 and 4. Further, a result in a case of using the piezoelectric layer 2 made of LiNbO₃ in Z-cut is illustrated in FIG. 9, but the same tendency is obtained in a case of using the piezoelectric layer 2 in another cut angle.

In a region surrounded by an ellipse J in FIG. 9, the spurious component is as large as about 1.0. As is clear from FIG. 9, when the fractional bandwidth exceeds about 0.17, that is, when the fractional bandwidth exceeds about 17%, a large spurious component having a spurious level of about 1 or more appears in a pass band even when parameters regulating the fractional bandwidth are changed. That is, as in the resonance characteristics illustrated in FIG. 8, a large spurious component indicated by the arrow B appears in the band. The fractional bandwidth, therefore, is preferably, for example, about 17% or less. In this case, the spurious component may be made small by adjusting the film thickness of the piezoelectric layer 2, the measurements of the electrode fingers 3 and 4, and the like.

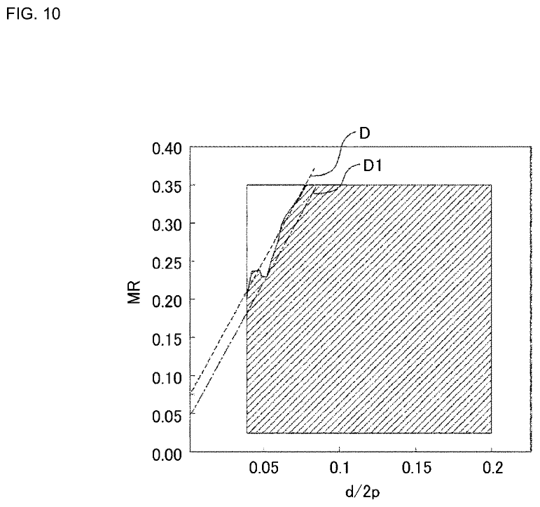

FIG. 10 is a diagram illustrating the relationship between d/2p, the metallization ratio MR, and the fractional bandwidth. Various acoustic wave devices 1 having different d/2p and MR are configured as the acoustic wave device 1 of the first example embodiment, and the fractional bandwidths are measured. The hatched portion on the right side of the broken line D in FIG. 10 is a region where the fractional bandwidth is about 17% or less. The boundary between the hatched region and the unhatched region is represented by MR=about 3.5 (d/2p)+0.075. That is, MR=about 1.75 (d/p)+0.075. Therefore, preferably, for example, MR≤about 1.75 (d/p)+0.075 is satisfied. In that case, the fractional bandwidth is easily set to about 17% or less. A region on the right side of MR=about 3.5 (d/2p)+0.05 indicated by a dashed-and-dotted line D1 in FIG. 10 is more preferable. That is, when MR ≤about 1.75 (d/p)+0.05, the fractional bandwidth may reliably be set to 17% or less.

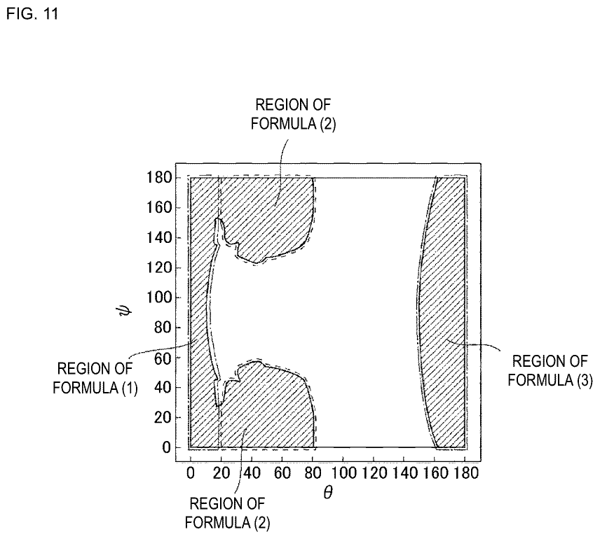

FIG. 11 is a diagram illustrating a map of the fractional bandwidth relative to Euler angles (0°, θ, ψ) of LiNbO₃ when d/p is made as close to 0 as possible. The hatched portion in FIG. 11 is a region where the fractional bandwidth of at least 5% or more is obtained. The range of the region is approximated to ranges represented by formula (1), formula (2), and formula (3) below.

$$\\ \begin{matrix}( 0 ° \pm 10 ° , 0 ° to 20 ° , any ψ ) & Formula ( 1 )\end{matrix}$$

$$\\ \begin{matrix}( 0 ° \pm 10 ° , 20 ° to 80 ° , 0 ° to 60 ° {( 1 - {( θ - 50 )}^{2} / 900 )}^{1 / 2} ) or & Formula ( 2 )\end{matrix}$$

$$\\ ( 0 ° \pm 10 ° , 20 ° to 80 ° , [ 180 ° - 60 ° {( 1 - {( θ - 50 )}^{2} / 900 )}^{1 / 2} ] to 180 ° )$$

$$\\ \begin{matrix}( 0 ° \pm 10 ° , [ 180 ° - 30 {° ( 1 - {( ψ - 90 )}^{2} / 8100 )}^{1 / 2} ] to 180 ° , any ψ ) & Formula ( 3 )\end{matrix}$$

When the Euler angles satisfy the range of formula (1), formula (2), or formula (3) above, the fractional bandwidth may sufficiently be widened and it is preferable.

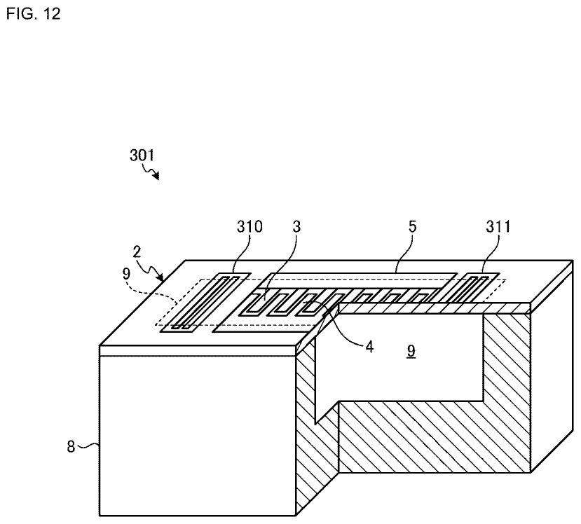

FIG. 12 is a partially cutaway perspective view illustrating the acoustic wave device according to an example embodiment of the present disclosure. In FIG. 12, an outer peripheral edge of the space 9 is indicated by a broken line. The acoustic wave device of the present disclosure may use a plate wave. In this case, as illustrated in FIG. 12, an acoustic wave device 301 includes reflectors 310 and 311. The reflectors 310 and 311 are provided on both sides of the electrode fingers 3 and 4 of the piezoelectric layer 2 in an acoustic wave propagation direction. In the acoustic wave device 301, an alternating electric field is applied to the electrode fingers 3 and 4 above the space 9 to excite a Lamb wave as a plate wave. At this time, since the reflectors 310 and 311 are provided on both sides, resonance characteristics by a Lamb wave as a plate wave may be obtained.

As described above, a bulk wave in a first-order thickness-shear mode is used in the acoustic wave devices 1 and 101. In the acoustic wave devices 1 and 101, the first electrode finger 3 and the second electrode finger 4 are electrodes adjacent to each other, and when the thickness of the piezoelectric layer 2 is represented as d and the center-to-center distance between the first electrode finger 3 and the second electrode finger 4 is represented as p, d/p is, for example, about 0.5 or less. Thus, even when the acoustic wave device is reduced in size, the Q factor may increase.

In the acoustic wave devices 1 and 101, the piezoelectric layer 2 is made of, for example, lithium niobate or lithium tantalate. The first electrode finger 3 and the second electrode finger 4, opposing each other in the direction intersecting the thickness direction of the piezoelectric layer 2, are provided on the first main surface 2a or on the second main surface 2b of the piezoelectric layer 2, and the first electrode finger 3 and the second electrode finger 4 are preferably covered with a protection film.

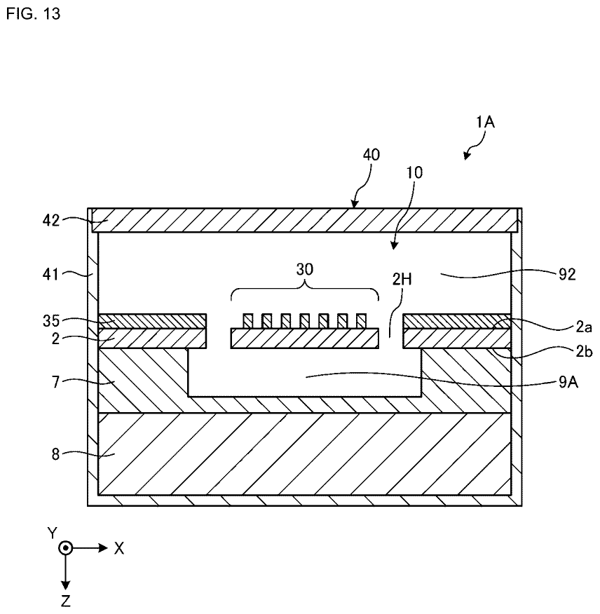

FIG. 13 is a sectional view illustrating an example of the acoustic wave device according to the first example embodiment. As illustrated in FIG. 13, an acoustic wave device 1A according to the first example embodiment includes an acoustic wave element 10 and a package 40. The acoustic wave element 10 includes a support portion, the piezoelectric layer 2, a functional electrode 30, and an interconnect electrode 35.

The support is preferably a portion including a support substrate 8. In the first example embodiment, the support includes the support substrate 8 and an intermediate layer 7. The support may include only the support substrate 8. The support includes the space 9A at a position where the space 9A at least partially overlaps the functional electrode 30 in a plan view in the Z-direction. In the example of FIG. 13, the space 9 is provided to the intermediate layer 7 on the piezoelectric layer 2 side, but this is merely an example, and the space 9A may pass through the intermediate layer 7 in the Z-direction and may be provided to the support substrate 8 on the piezoelectric layer 2 side. When the support includes only the support substrate 8, the space 9A may be provided to the support substrate 8 on the piezoelectric layer 2 side.

The piezoelectric layer 2 is provided in the Z-direction of the support. In the first example embodiment, the piezoelectric layer 2 includes a through-hole 2H passing through the piezoelectric layer 2 in the Z-direction. In the first example embodiment, the through-hole 2H is provided at a position overlapping a space 9A in a plan view in the Z-direction. In the example of FIG. 13, two through-holes 2H are provided on both sides of the functional electrode 30 in the X-direction. The through-hole 2H communicates with the space 9A. This may reduce or prevent the pressure difference between the space 9A and the outside of the space 9A, and prevent damage to the piezoelectric layer 2.

The functional electrode 30 is, for example, an IDT electrode. That is, the functional electrode 30 includes the first electrode finger 3, the second electrode finger 4, the first busbar electrode 5, and the second busbar electrode 6. In the example of FIG. 13, the functional electrode 30 is provided on the first main surface 2a of the piezoelectric layer 2, but the structure is not limited thereto, and the functional electrode 30 may be provided on the second main surface 2b.

The interconnect electrode 35 is electrically coupled to the functional electrode 30. The interconnect electrode 35 is preferably made of an appropriate metal or an alloy such as, for example, Al or an AlCu alloy. In the example of FIG. 13, the interconnect electrode 35 is provided on the first main surface 2a of the piezoelectric layer 2, but this is merely an example.

The package 40 houses the acoustic wave element 10. In the first example embodiment, the package 40 includes a case 41 and a lid 42. The case 41 is a box-shaped portion including an opening on one surface in the Z-direction. The lid 42 is preferably a plate-shaped portion closing the opening of the case 41. The inside of the package 40 may be made liquid-tight by sealing the case 41 with the lid 42 after the acoustic wave element 10 is housed in the case 41. In the first example embodiment, the package 40 preferably includes a second space 92. The second space 92 is a space between the first main surface 2a of the piezoelectric layer 2 and the lid 42 in the Z-direction. That is, the second space 92 is a space inside the package 40 and outside the space 9A. In the first example embodiment, the package 40 is not air-tight, but allows a gas to pass through. Specifically, the package 40 is made of a breathable resin, for example, but is not limited thereto as long as the second space 92 is liquid-tight and allows a gas to pass through to the outside of the package 40. For example, a portion of the package 40 may be made of the breathable resin, or the package 40 may be provided with a vent hole through which a gas passes and with which the second space 92 and the outside of the package 40 communicate with each other. As a result, the space 9A, the second space 92, and the outside of the package 40 have the same or substantially the same air pressure, and communicate with each other through at least one path. In the first example embodiment, the one path refers to a path through which a gas can move, the path connecting the space 9A to the outside of the package 40 via the through-hole 2H, the second space 92, and the package 40. This may reduce or prevent damage to the piezoelectric layer 2 due to the air pressure difference between the space 9A, the second space 92, and the outside of the package 40.

As described above, the acoustic wave device 1A according to the first example embodiment includes the acoustic wave element 10 and the package 40 to house the acoustic wave element 10. The acoustic wave element 10 preferably includes a support including the support substrate 8 having a thickness in the first direction, the piezoelectric layer 2 laminated on the support and including the first main surface 2a and the second main surface 2b opposite to the first main surface 2a in the first direction, and the functional electrode 30 provided on at least one of the first main surface 2a and the second main surface 2b of the piezoelectric layer 2. The support includes a first space (space 9A) on the piezoelectric layer 2 side at a position where the first space at least partially overlaps the functional electrode 30 in a plan view in the first direction. The package 40 includes the second space 92 outside the space 9A, the piezoelectric layer 2 has a through-hole 2H communicating with the first space and the second space 92, and the first space, the second space 92, and the outside of the package 40 communicate with each other through at least one path. This may reduce or prevent damage to the piezoelectric layer 2 due to the air pressure difference between the first space, the second space 92, and the package 40.

Further, the acoustic wave device 1A according to the first example embodiment includes the acoustic wave element 10 and the package 40 to house the acoustic wave element 10. The acoustic wave element 10 includes a support including the support substrate 8 having a thickness in the first direction, the piezoelectric layer 2 laminated on the support and having the first main surface 2a and the second main surface 2b opposite to the first main surface 2a in the first direction, and the functional electrode 30 provided on at least one of the first main surface 2a and the second main surface 2b of the piezoelectric layer 2. The support includes the first space (space 9A) on the piezoelectric layer 2 side at a position where the first space at least partially overlaps the functional electrode 30 in a plan view in the first direction. The package 40 includes the second space 92 outside the space 9A, the piezoelectric layer 2 plate-shaped member includes a through-hole 2H communicating with the first space and the second space 92, and the first space, the second space 92, and the outside of the package 40 have the same air pressure. This may reduce or prevent damage to the piezoelectric layer 2 due to the air pressure difference between the first space, the second space 92, and the package 40.

As an example embodiment, the package 40 is at least partially made of the breathable resin, for example. This may allow a gas to move between the second space 92 and the outside of the package 40, while keeping the second space 92 liquid-tight.

As an example embodiment, the functional electrode 30 is preferably, for example, an IDT electrode. This makes it possible to reduce the acoustic wave device 1 in size and raise the Q factor.

As an example embodiment, the functional electrode 30 includes the plurality of first electrode fingers 3 extending in the second direction intersecting the first direction, the first busbar electrode 5 to which the plurality of first electrode fingers 3 are coupled, the plurality of second electrode fingers 4 each opposing corresponding one of the plurality of first electrode fingers 3 in the third direction orthogonal or substantially orthogonal to the second direction and extending in the second direction, and the second busbar electrode 6 to which the plurality of second electrode fingers 4 are coupled. When p represents the center-to-center distance between the first electrode finger 3 and the second electrode finger 4 adjacent to each other, among the plurality of first electrode fingers 3 and the plurality of second electrode fingers 4, the thickness of the piezoelectric layer 2 is, for example, about 2p or less. This makes it possible to reduce the acoustic wave device 1 in size and raise the Q factor.

As an example embodiment, the piezoelectric layer 2 preferably includes lithium niobate or lithium tantalate, for example. This makes it possible to provide an acoustic wave device having good resonance characteristics.

As an example embodiment, the acoustic wave device is configured to generate a plate wave. This makes it possible to provide an acoustic wave device that may have a high coupling coefficient and good resonance characteristics.

As an example embodiment, the acoustic wave device is configured to generate a bulk wave in a thickness-shear mode. This makes it possible to provide an acoustic wave device that may have a high coupling coefficient and good resonance characteristics.

As an example embodiment, the functional electrode 30 preferably includes the plurality of first electrode fingers 3 extending in the second direction intersecting the first direction, the first busbar electrode 5 to which the plurality of first electrode fingers 3 are coupled, the plurality of second electrode fingers 4 each opposing a corresponding one of the plurality of first electrode fingers 3 in the third direction orthogonal to the second direction and extending in the second direction, and the second busbar electrode 6 to which the plurality of second electrode fingers 4 are coupled. When d represents the thickness of the piezoelectric layer 2 and p represents the center-to-center distance between the first electrode finger 3 and the second electrode finger 4 adjacent to each other, d/p is, for example, about 0.5 or less. This makes it possible to reduce the acoustic wave device 1 in size and raise the Q factor.

As an example embodiment, d/p is, for example, about 0.24 or less. This makes it possible to reduce the acoustic wave device 1 in size and raise the Q factor.

As an example embodiment, the functional electrode 30 preferably includes the plurality of first electrode fingers 3 extending in the second direction intersecting the first direction, the first busbar electrode 5 to which the plurality of first electrode fingers 3 are coupled, the plurality of second electrode fingers 4 each opposing corresponding one of the plurality of first electrode fingers 3 in the third direction orthogonal to the second direction and extending in the second direction, and the second busbar electrode 6 to which the plurality of second electrode fingers 4 are coupled. The metallization ratio MR satisfies MR≤about 1.75 (d/p)+0.075, where MR is a ratio of the first electrode finger 3 and the second electrode finger 4 to the excitation region C where the first electrode finger 3 and the second electrode finger 4 are overlapping each other when viewed in the third direction. In this case, the fractional bandwidth may reliably be set to about 17% or less.

As an example embodiment, the piezoelectric layer 2 is preferably made of lithium niobate or lithium tantalate, for example, and the Euler angles (φ, θ, ψ) of lithium niobate or lithium tantalate are in the range of formula (1), formula (2), or formula (3) below. In this case, the fractional bandwidth may sufficiently be widened.

$$\\ \begin{matrix}( 0 ° \pm 10 ° , 0 ° to 20 ° , any ψ ) & Formula ( 1 )\end{matrix}$$

$$\\ \begin{matrix}( 0 ° \pm 10 ° , 20 ° to 80 ° , 0 ° to 60 ° {( 1 - {( θ - 50 )}^{2} / 900 )}^{1 / 2} ) or & Formula ( 2 )\end{matrix}$$

$$\\ ( 0 ° \pm 10 ° , 20 ° to 80 ° , [ 180 ° - 60 ° {( 1 - {( θ - 50 )}^{2} / 900 )}^{1 / 2} ] to 180 ° )$$

$$\\ \begin{matrix}( 0 ° \pm 10 ° , [ 180 ° - 30 {° ( 1 - {( ψ - 90 )}^{2} / 8100 )}^{1 / 2} ] to 180 ° , any ψ ) & Formula ( 3 )\end{matrix}$$

An example of a method for manufacturing the acoustic wave device 1A according to the first example embodiment will be described below with reference to the drawings. The following manufacturing method is merely an example, and the method is not limited thereto.

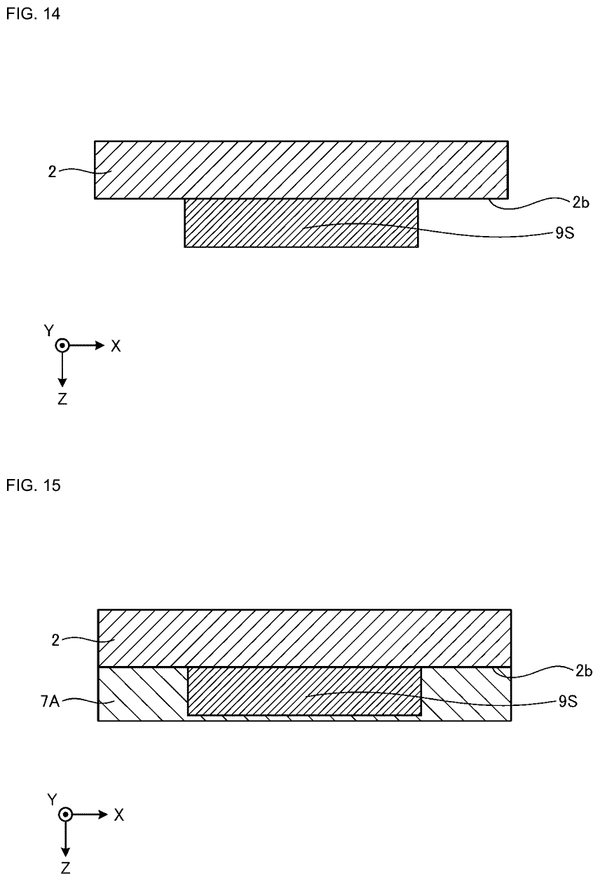

FIG. 14 is a schematic sectional view illustrating a sacrificial layer forming step in the method for manufacturing the acoustic wave device according to the first example embodiment. As illustrated in FIG. 14, in the sacrificial layer forming step, the sacrificial layer 9S is formed on a portion of the second main surface 2b of the piezoelectric layer 2.

FIG. 15 is a schematic sectional view illustrating an intermediate layer forming step in the method for manufacturing the acoustic wave device according to the first example embodiment. As illustrated in FIG. 15, in the intermediate layer forming step, a first portion 7A of the intermediate layer 7 is formed on the second main surface 2b of the piezoelectric layer 2 and the sacrificial layer 9S. A surface of the first portion 7A is made flat so that unevenness caused by the sacrificial layer 9S is eliminated.

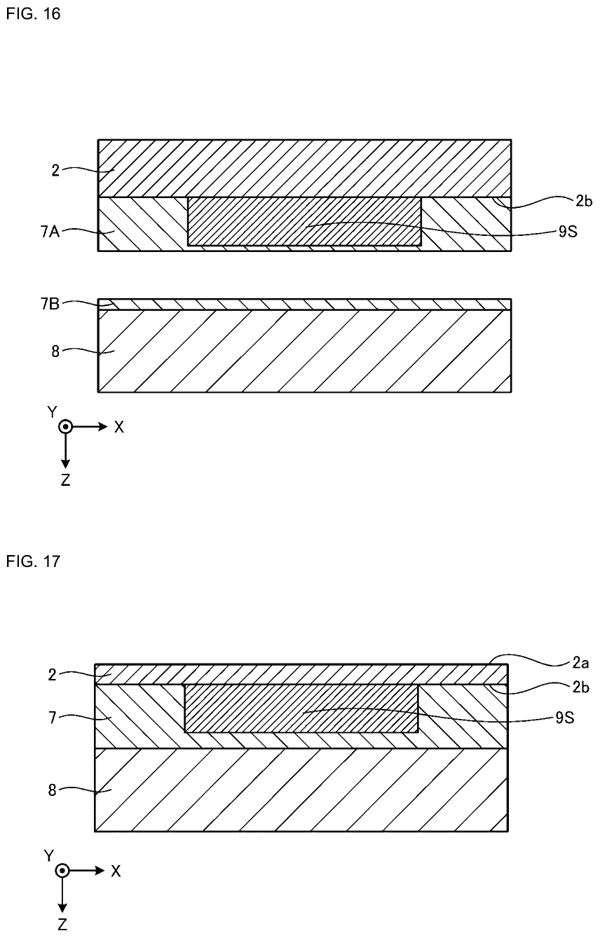

FIG. 16 is a schematic sectional view illustrating a bonding step in the method for manufacturing the acoustic wave device according to the first example embodiment. As illustrated in FIG. 16, in the bonding step, the piezoelectric layer 2 is bonded to the support substrate 8 with the intermediate layer 7 interposed therebetween. More specifically, the first portion 7A of the intermediate layer 7 formed on the piezoelectric layer 2 and a second portion 7B of the intermediate layer 7 formed on the support substrate 8 are bonded to each other. Thus, the piezoelectric layer 2 (piezoelectric substrate) is supported by the support substrate 8.

FIG. 17 is a schematic sectional view illustrating a piezoelectric layer polishing step in the method for manufacturing the acoustic wave device according to the first example embodiment. As illustrated in FIG. 17, in the piezoelectric layer polishing step, the surface of the piezoelectric layer 2 opposite to the second main surface 2b in the thickness direction is polished to reduce the thickness of the piezoelectric layer 2, thereby forming the first main surface 2a.

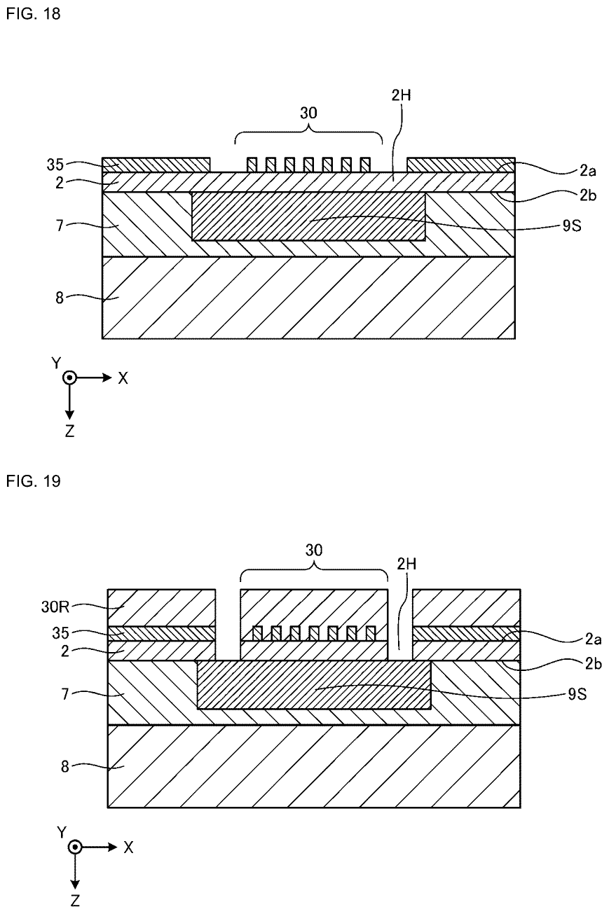

FIG. 18 is a schematic sectional view illustrating an electrode forming step in the method for manufacturing the acoustic wave device according to the first example embodiment. As illustrated in FIG. 18, in the electrode forming step, the functional electrode 30 and the interconnect electrode 35 are formed on the first main surface 2a of the piezoelectric layer 2 by lift-off.

FIG. 19 is a schematic sectional view illustrating a through-hole forming step in the method for manufacturing the acoustic wave device according to the first example embodiment. As illustrated in FIG. 19, in the through-hole forming step, a resist 30R is formed on the first main surface 2a of the piezoelectric layer 2, and the through-hole 2H is formed in the piezoelectric layer 2 by dry etching. After the formation of the through-hole 2H, the resist 30R is removed.

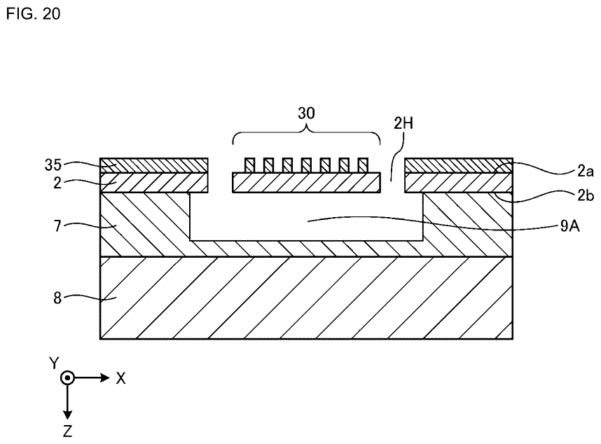

FIG. 20 is a schematic sectional view illustrating a sacrificial layer removal step in the method for manufacturing the acoustic wave device according to the first example embodiment. As illustrated in FIG. 20, in the sacrificial layer removal step, etchant is poured into the through-hole 2H subjected to resist patterning to remove the sacrificial layer 9S. Thus, the space 9A is formed.

The acoustic wave element 10 of the acoustic wave device 1A according to the first example embodiment is manufactured by the above-described steps. Frequency characteristics of the acoustic wave element 10 are inspected and adjusted, as necessary. Thereafter, the acoustic wave element 10 is housed in the case 41, and the cavity of the case 41 is closed by the lid 42, whereby the acoustic wave device 1A according to the first example embodiment is manufactured.

As described above, the method for manufacturing the acoustic wave device 1A according to the first example embodiment described above includes the sacrificial layer forming step of forming the sacrificial layer 9S on a portion of one of a pair of main surfaces of the piezoelectric layer 2 including the pair of main surfaces opposite to each other in the thickness direction, the intermediate layer forming step of forming the intermediate layer 7 on one main surface of the piezoelectric layer 2 and the sacrificial layer 9S, the bonding step of bonding the piezoelectric layer 2 to the support substrate 8 with the intermediate layer 7 interposed therebetween, the electrode forming step of forming the electrode (functional electrode 30 and interconnect electrode 35) on at least one of the pair of main surfaces of the piezoelectric layer 2, the through-hole forming step of forming the through-hole 2H in the piezoelectric layer 2, and the sacrificial layer removal step of removing the sacrificial layer 9S. Thus, the first space formed by removing the sacrificial layer 9S and the space outside the first space communicate with each other, and therefore, it is possible to reduce or prevent damage to the piezoelectric layer 2 due to the air pressure difference between the inside and the outside of the space 9A.

### Second Example Embodiment

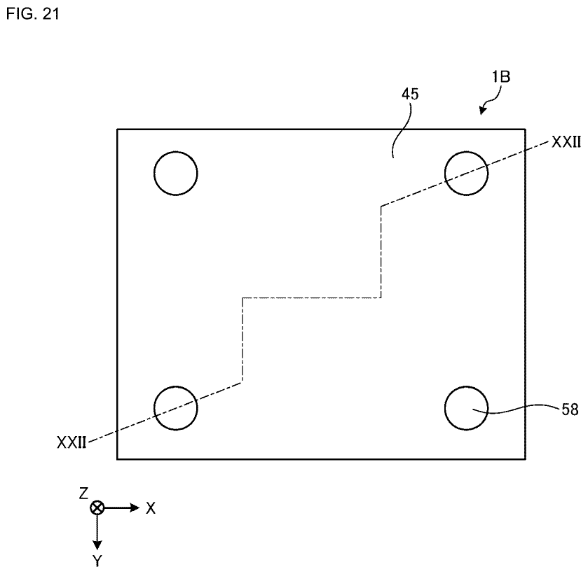

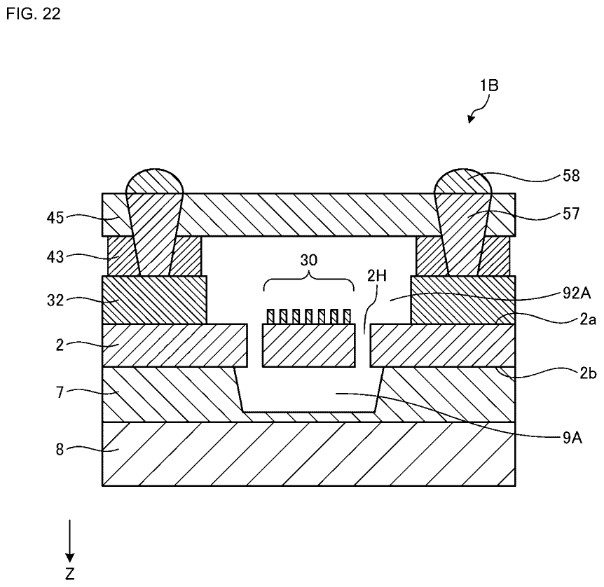

FIG. 21 is a plan view of an acoustic wave device according to a second example embodiment of the present invention. FIG. 22 is a sectional view of the acoustic wave device in FIG. 21 taken along line XXII-XXII. An acoustic wave device 1B according to the second example embodiment is different from the first example embodiment in that a support frame 43 and a cover 45 are provided instead of the package 40. The acoustic wave device 1B according to the second example embodiment will be described below with reference to the drawings. The same or corresponding components as those of the acoustic wave device 1A according to the first example embodiment are represented by the same reference signs, and a description thereof will be omitted.

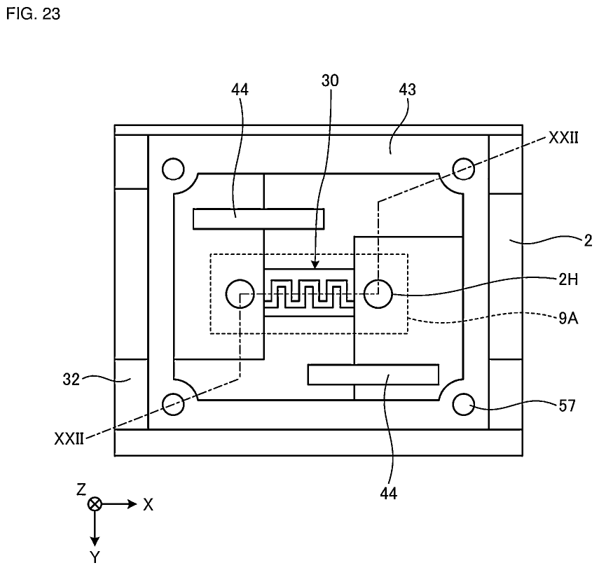

FIG. 23 is a plan view of a portion of the acoustic wave device according to the second example embodiment. FIG. 23 is a view of the acoustic wave device 1B from which the cover 45 is removed. As illustrated in FIG. 21 to FIG. 23, the acoustic wave device 1B preferably includes a support portion, a piezoelectric layer 2, a functional electrode 30, an interconnect electrode 32, the support frame 43, an internal support 44, and the cover 45.

The interconnect electrode 32 is provided on a first main surface 2a of the piezoelectric layer 2. The interconnect electrode 32 is made of an appropriate metal or an alloy such as, for example, Al or an AlCu alloy. In the example of FIG. 22, the interconnect electrode 32 is provided at positions that do not overlap the space 9A in a plan view in the Z-direction. The interconnect electrode 32 is electrically coupled to the functional electrode 30.

The support frame 43 is a support to make the piezoelectric layer 2 be supported by the cover 45. The support frame 43 is preferably made of a photosensitive resin, for example. In the example illustrated in FIG. 23, the support frame 43 is formed in a linear pattern so as to surround the functional electrode 30 in a plan view in the Z-direction. One surface of the support frame 43 in the Z-direction is bonded to the interconnect electrode 32, and the other surface of the support frame 43 in the Z-direction is bonded to the cover 45. The support frame 43 includes a second space 92A. The second space 92A is a space inside the support frame 43 and is a space between the piezoelectric layer 2 and the cover 45 described later.

The internal support 44 is a support to make the piezoelectric layer 2 be supported by the cover 45. The internal support 44 is preferably made of the photosensitive resin, for example. In the example illustrated in FIG. 23, the internal support 44 is provided in the second space 92A. The internal support 44 is provided at a position not overlapping the space 9A in a plan view in the Z-direction. One surface of the internal support 44 in the Z-direction is in contact with the first main surface 2a of the piezoelectric layer 2 or the interconnect electrode 32. The other surface of the internal support 44 in the Z-direction is in contact with the cover 45. Thus, the cover 45 is also supported by the internal support 44, and the strength of the cover 45 may be increased. Note that the internal support 44 may be omitted if so desired.

The cover 45 is a sheet provided on the support frame 43 and the internal support 44. The cover 45 is preferably made of resin, for example. The cover 45 is fixed to the support frame 43 by a terminal electrode 57.

In the second example embodiment, a liquid cannot pass through the support frame 43 and the cover 45. At least one of the support frame 43 and the cover 45 allows a gas to pass through. Specifically, at least one of the support frame 43 and the cover 45 is made of the breathable resin, for example, but the structure is not limited thereto as long as the second space 92A is liquid-tight and allows a gas to pass through to the outside of the cover 45. For example, a portion of the support frame 43 or the cover 45 may be made of the breathable resin, or the support frame 43 or the cover 45 may be provided with a vent hole through which a gas passes and with which the second space 92A and the outside of the cover 45 communicate with each other. Thus, the second space 92A becomes liquid-tight but does not become air-tight. As a result, the space 9A, the second space 92A, and the outside of the cover 45 have the same or substantially the same air pressure, and communicate with each other through at least one path. In the second example embodiment, the one path refers to a path through which a gas can move, the path connecting the space 9A to the outside of the cover 45 via the through-hole 2H, the second space 92A, and the support frame 43 or the cover 45. This may reduce or prevent damage to the piezoelectric layer 2 due to the air pressure difference between the space 9A, the second space 92A, and the outside of the cover 45.

The terminal electrode 57 is preferably a multilayer body including, for example, an Au layer that is plated on a Cu layer and a Ni layer. The terminal electrode 57 is provided so as to pass through the support frame 43 and the cover 45. The terminal electrode 57 is a bump metal and is electrically coupled to the interconnect electrode 32.

The terminal electrode 57 is provided with a bump 58. The bump 58 is a bump metal, and is, for example, a ball grid array (BGA) bump. The bump 58 is laminated on the terminal electrode 57 in the Z-direction, and is electrically coupled to the terminal electrode 57. Thus, the bump 58 to the functional electrode 30 are electrically coupled.

The acoustic wave device 1B according to the second example embodiment has been described above, but the acoustic wave device according to the second example embodiment is not limited to that illustrated in FIG. 22. For example, the acoustic wave device 1B may include a plurality of spaces 9A, and a plurality of resonators may be provided.

As described above, the acoustic wave device 1B according to the second example embodiment includes the support including the support substrate 8 having a thickness in the first direction, the piezoelectric layer 2 laminated on the support and having the first main surface 2a and the second main surface 2b opposite to the first main surface 2a in the first direction, the functional electrode 30 provided on at least one of the first main surface 2a and the second main surface 2b of the piezoelectric layer 2, the support frame 43 provided on the piezoelectric layer 2 in the first direction, and the cover 45 provided on the support frame 43 in the first direction. The support includes the first space (space 9A) on the piezoelectric layer 2 side at a position where the first space at least partially overlaps the functional electrode 30 in a plan view in the first direction, the support frame 43 includes the second space 92A, the piezoelectric layer 2 includes the through-hole 2H through which the first space and the second space 92A communicate with each other, and the first space, the second space 92A, and the outside of the cover 45 communicate with each other through at least one path. This may reduce or prevent damage to the piezoelectric layer 2 due to the air pressure difference between the first space, the second space 92A, and the outside of the cover 45.

The acoustic wave device 1B according to the second example embodiment includes the support including the support substrate 8 having a thickness in the first direction, the piezoelectric layer 2 laminated on the support and having the first main surface 2a and the second main surface 2b opposite to the first main surface 2a in the first direction, the functional electrode 30 provided on at least one of the first main surface 2a and the second main surface 2b of the piezoelectric layer 2, the support frame 43 provided on the piezoelectric layer 2 in the first direction, and the cover 45 provided on the support frame 43 in the first direction. The support includes the first space (space 9A) on the piezoelectric layer 2 side at a position where the first space at least partially overlaps the functional electrode 30 in a plan view in the first direction, the support frame 43 includes the second space 92A, the piezoelectric layer 2 includes the through-hole 2H through which the first space and the second space 92A communicate with each other, and the first space, the second space 92A, and the outside of the cover 45 have the same or substantially the same air pressure. This may reduce or prevent damage to the piezoelectric layer 2 due to the air pressure difference between the first space, the second space 92A, and the outside of the cover 45.

As an example embodiment, at least one of the support frame 43 and the cover 45 is at least partially made of the breathable resin, for example. This may allow a gas to pass through the cover 45, while keeping the second space 92A liquid-tight.

An example of a method for manufacturing the acoustic wave device 1B according to the second example embodiment will be described below. The method for manufacturing the acoustic wave device 1B according to the second example embodiment is the same or substantially the same as the method for manufacturing the acoustic wave device 1A according to the first example embodiment from the sacrificial layer forming step to the sacrificial layer removal step, and thus a description thereof will be omitted. The following manufacturing method is merely an example, and the method is not limited thereto.

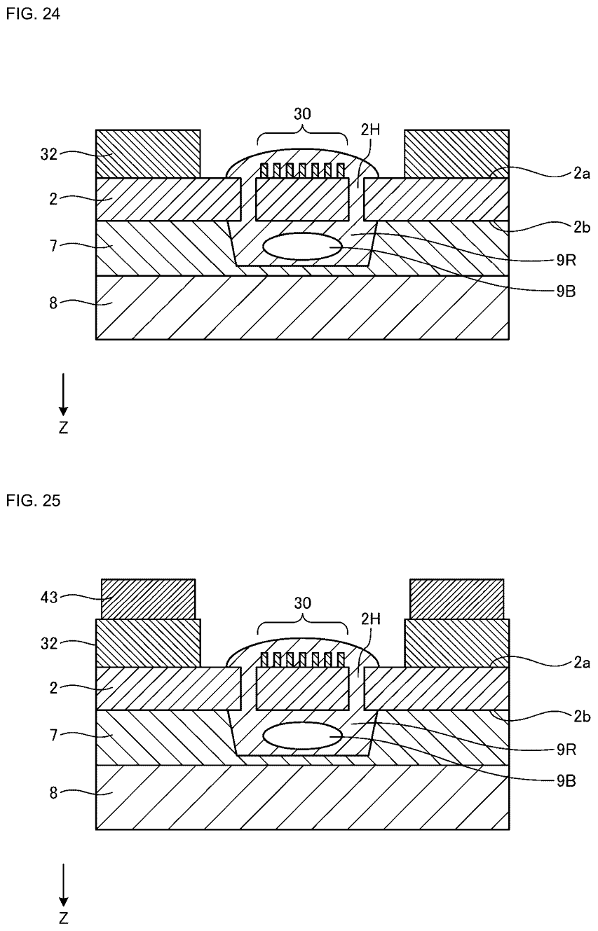

FIG. 24 is a diagram illustrating a filler filling step in the method for manufacturing the acoustic wave device according to the second example embodiment. In the filler filling step, a filler 9R is injected from the through-hole 2H. At this time, as illustrated in FIG. 24, the filler 9R is injected so as to cover the inner wall of the space 9A, the inner wall of the through-hole 2H, and the functional electrode 30. Thus, in the support frame forming step described later, the piezoelectric layer 2 at a position overlapping the space 9A in a plan view in the Z-direction is protected, and this may reduce or prevent damage to the piezoelectric layer 2. In the filler filling step, the space 9A need not be filled with the filler 9R, and a bubble 9B may be generated in the space 9A.

The filler 9R contains a non-photosensitive resin. This may prevent the filler 9R from being removed in the support frame forming step described later. The filler 9R is not limited to the above and may be resist, for example, as long as the filler 9R is a material that is not removed by a developer in the support frame forming step and can be removed by a solution that does not dissolve the support frame 43 in a filler etching step.

FIG. 25 is a diagram illustrating the support frame forming step in the method for manufacturing the acoustic wave device according to the second example embodiment. As illustrated in FIG. 25, in the support frame forming step, the support frame 43 and the internal support 44 are formed on the piezoelectric layer 2. More specifically, the photosensitive resin is applied to the first main surface 2a of the piezoelectric layer 2 where the interconnect electrode 32 and the filler 9R are present, and the portion other than the support frame 43 and the internal support 44 is removed by exposure and development. Here, since the filler 9R is made of a material which does not react with the developer, the support frame 43 and the internal support 44 may be formed while protecting the piezoelectric layer 2.

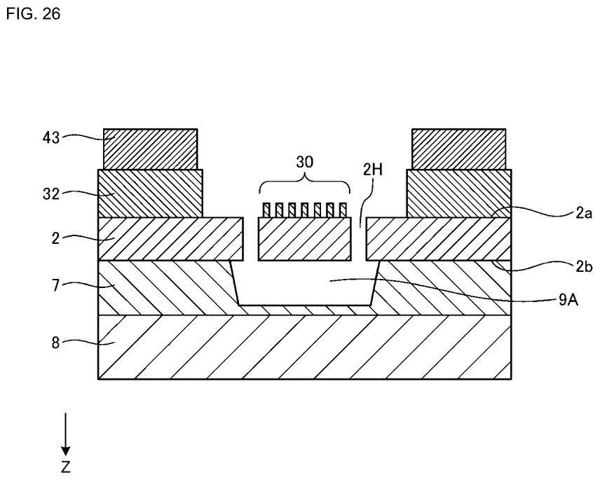

FIG. 26 is a diagram illustrating the filler etching step in the method for manufacturing the acoustic wave device according to the second example embodiment. As illustrated in FIG. 26, in the filler etching step, the filler 9R is etched by etchant. The etchant for the filler 9R is a solution that does not dissolve the support frame 43. This makes it possible to completely remove the residue in the space 9A and reduce or prevent deterioration in frequency characteristics.

After the filler etching, the cover 45 is provided on the support frame 43. The terminal electrode 57 is provided so as to pass through the cover 45 in the Z-direction. The bump 58 is, then, laminated on the terminal electrode 57. The acoustic wave device 1B is manufactured through the above-described steps.

As described above, the method for manufacturing the acoustic wave device 1B according to the second example embodiment further includes the filler filling step of filling the filler 9R in the through-hole 2H, the support frame forming step of forming the support frame 43 on the piezoelectric layer 2, and the filler etching step of etching the filler 9R. Thus, the piezoelectric layer 2 is protected in the support frame forming step, and this may reduce or prevent damage to the piezoelectric layer 2.

As an example embodiment, the filler 9R includes the non-photosensitive resin, for example. Thus, when the support frame 43 is formed of a photosensitive material, the filler 9R may be prevented from being affected by exposure and development in the support frame forming step.

### Third Example Embodiment

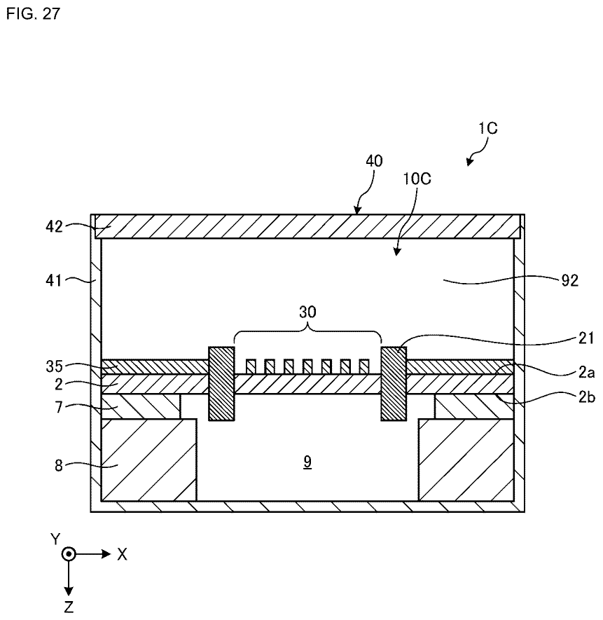

FIG. 27 is a sectional view of an acoustic wave device according to a third example embodiment of the present invention.

An acoustic wave device 1C according to the third example embodiment differs from the first example embodiment in that a through-plug 21 is further provided. The acoustic wave device 1C according to the third example embodiment will be described below with reference to the drawings. The same or corresponding components as those of the acoustic wave device 1A according to the first example embodiment are represented by the same reference signs, and a description thereof will be omitted.

As illustrated in FIG. 27, in the third example embodiment, the support includes a space 9. The space 9 is a space that passes through the support in the Z-direction. In the example of FIG. 27, a cavity 7a exposed to the space 9 is positioned inside a cavity 8a exposed to the space 9 in a plan view in the Z-direction.

As illustrated in FIG. 27, the through-plug 21 is provided so as to pass through a piezoelectric layer 2. Here, the through-plug 21 is provided in a through-hole 2H formed in the piezoelectric layer 2. That is, the through-hole 2H is closed by the through-plug 21. The through-plug 21 is made of a material through which a liquid cannot pass but a gas can pass, and is made of the photosensitive polyimide resin, for example. This makes the space 9 and a second space 92 have the same or substantially the same air pressure, while keeping the space 9 liquid-tight, and communicate with each other through at least one path. In the third example embodiment, the one path refers to a path through which a gas can move, the path connecting the space 9 to the outside of the package 40 via the through-plug 21, the second space 92, and the package 40. This may prevent damage to the piezoelectric layer 2 due to the air pressure difference between the space 9, the second space 92, and the outside of the package 40.

As described above, the acoustic wave device 1C according to the third example embodiment further includes the through-plug 21 that is provided in the through-hole 2H and passes through the piezoelectric layer 2, and the through-plug 21 is breathable. This makes it possible to make the space 9 liquid-tight while keeping the air pressure in the space 9 and the air pressure in the second space 92 equal to each other.

As an example embodiment, the through-plug 21 includes the photosensitive polyimide resin, for example. In this case, the acoustic wave device 1C is easily manufactured. Thus, the through-plug 21 does not allow a liquid to pass through, but allows a gas to pass through. This makes it possible to reduce or prevent a pressure difference between the space 9 and the second space 92, while keeping the space 9 liquid-tight.

An example of a method for manufacturing the acoustic wave device according to the third example embodiment will be described below. The following manufacturing method is merely an example, and the method is not limited thereto.

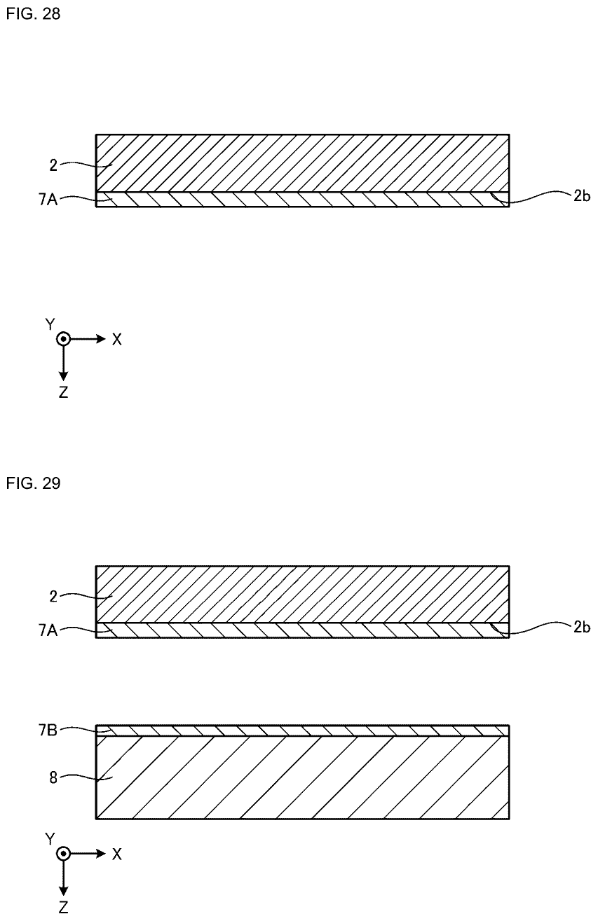

FIG. 28 is a schematic sectional view illustrating an intermediate layer forming step in the method for manufacturing the acoustic wave device according to the third example embodiment. As illustrated in FIG. 28, in the intermediate layer forming step, a first portion 7A of an intermediate layer 7 is formed on a second main surface 2b of the piezoelectric layer 2.

FIG. 29 is a schematic sectional view illustrating a bonding step in the method for manufacturing the acoustic wave device according to the third example embodiment. As illustrated in FIG. 29, in the bonding step, the piezoelectric layer 2 is bonded to a support substrate 8 with the intermediate layer 7 interposed therebetween. More specifically, the first portion 7A of the intermediate layer 7 formed on the piezoelectric layer 2 and a second portion 7B of the intermediate layer 7 formed on the support substrate 8 are bonded to each other. Thus, the piezoelectric layer 2 (piezoelectric substrate) is supported by the support substrate 8.

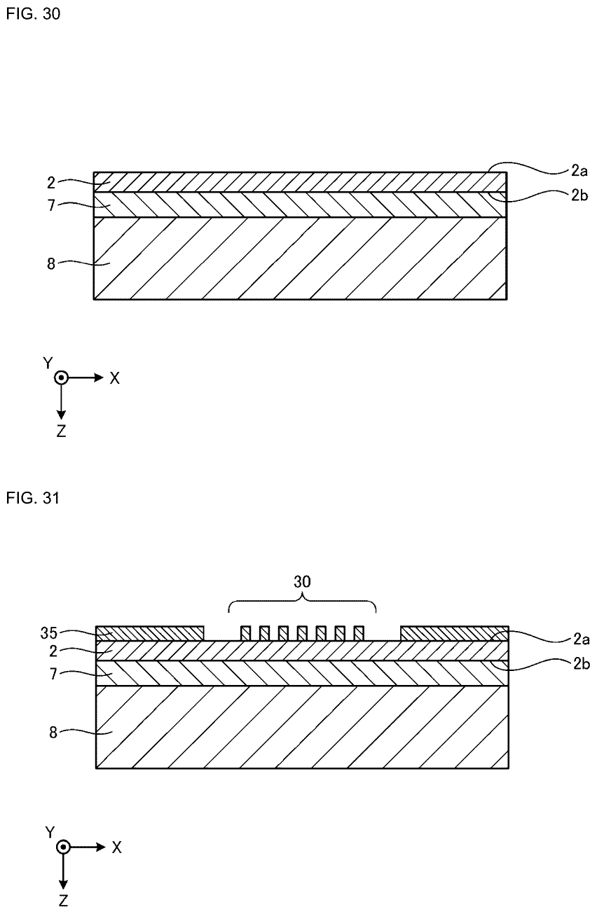

FIG. 30 is a schematic sectional view illustrating a piezoelectric layer polishing step in the method for manufacturing the acoustic wave device according to the third example embodiment.

As illustrated in FIG. 30, in the piezoelectric layer polishing step, the surface of the piezoelectric layer 2 opposite to the second main surface 2b in the thickness direction is polished to reduce the thickness of the piezoelectric layer 2, thereby forming a first main surface 2a.

FIG. 31 is a schematic sectional view illustrating an electrode forming step in the method for manufacturing the acoustic wave device according to the third example embodiment. As illustrated in FIG. 31, in the electrode forming step, a functional electrode 30 and an interconnect electrode 35 are formed on the first main surface 2a of the piezoelectric layer 2 by lift-off.

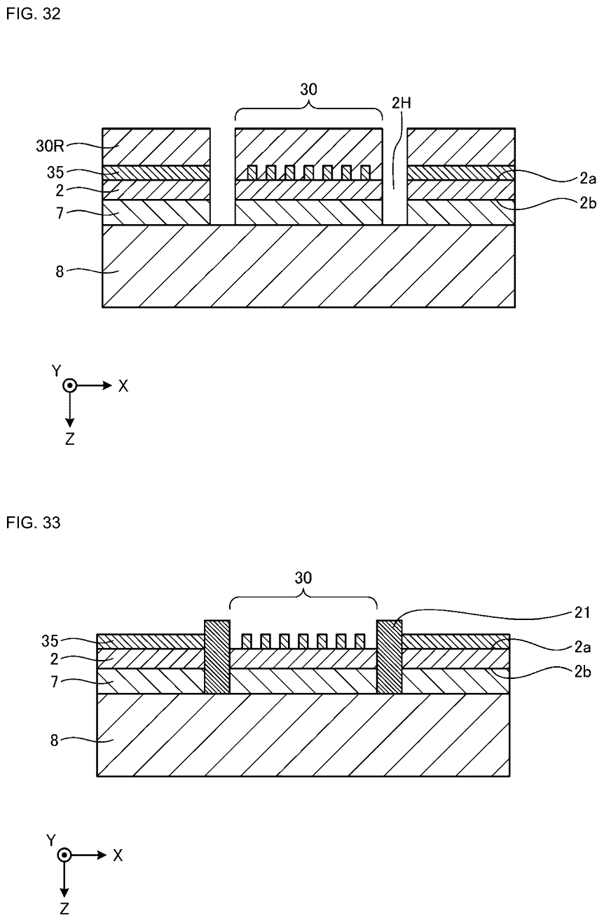

FIG. 32 is a schematic sectional view illustrating a through-hole forming step in the method for manufacturing the acoustic wave device according to the third example embodiment. As illustrated in FIG. 32, in the through-hole forming step, a resist 30R is formed on the first main surface 2a of the piezoelectric layer 2, and the through-hole 2H is formed in the piezoelectric layer 2 and the intermediate layer 7 by dry etching. After the formation of the through-hole 2H, the resist 30R is removed.

FIG. 33 is a diagram illustrating a through-plug forming step in the method for manufacturing the acoustic wave device according to the third example embodiment. As illustrated in FIG. 33, in the through-plug forming step, the through-plug 21 is formed so as to close the through-hole 2H. Specifically, the through-plug 21 is made of a photosensitive resin and formed by exposure and development.

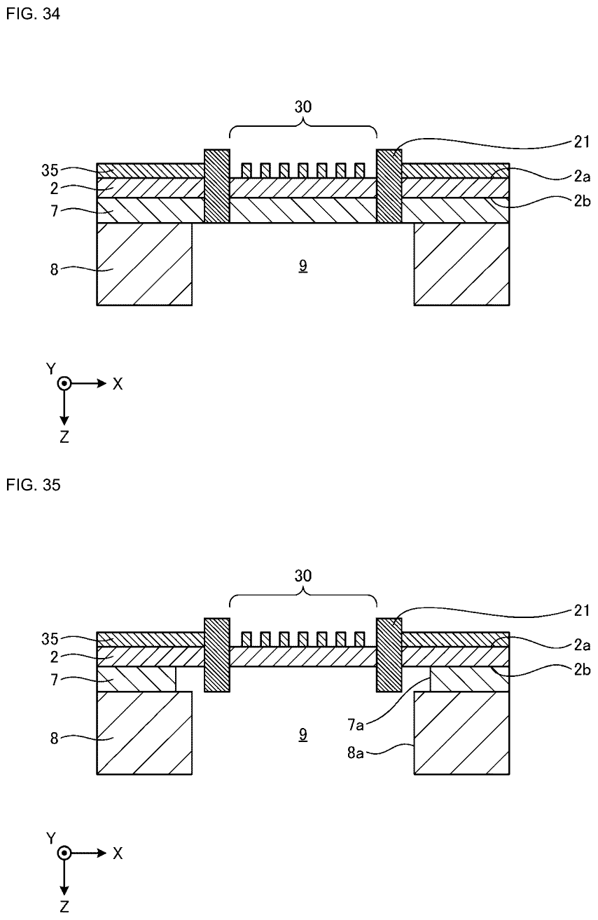

FIG. 34 is a schematic sectional view illustrating a first etching step in the method for manufacturing the acoustic wave device according to the third example embodiment. As illustrated in FIG. 34, in the first etching step, the space 9 is preferably formed by etching a portion of the support substrate 8 by dry etching such as, for example, deep reactive ion etching (DRIE).

FIG. 35 is a schematic sectional view illustrating a second etching step in the method for manufacturing the acoustic wave device according to the third example embodiment. As illustrated in FIG. 35, in the second etching step, the space 9 is widened in the thickness direction by etching part of the intermediate layer 7. The through-plug 21 is not etched, and only the intermediate layer 7 is etched. In this case, the cavity 7a exposed to the space 9 is positioned inside the cavity 8a exposed to the space 9 in a plan view in the Z-direction.

An acoustic wave element 10C of the acoustic wave device 1C according to the third example embodiment is manufactured by the above steps. Frequency characteristics of the acoustic wave element 10C are inspected and adjusted, as necessary. Thereafter, the acoustic wave element 10C is housed in the case 41, and the cavity of the case 41 is closed by the lid 42, whereby the acoustic wave device 1C according to the third example embodiment is manufactured.

As described above, the method for manufacturing the acoustic wave device 1C according to the third example embodiment includes the intermediate layer forming step of forming the intermediate layer 7 on the support substrate 8, the piezoelectric layer forming step of forming the piezoelectric layer 2 on the intermediate layer 7, the electrode forming step of forming the electrode (functional electrode 30 and interconnect electrode 35) on the piezoelectric layer 2, the through-hole forming step of forming the through-hole 2H in the piezoelectric layer 2 and the intermediate layer 7, the first etching step of forming the space 9 in part of the support substrate 8, and the second etching step of etching the intermediate layer 7 exposed to the space 9. Thus, the space 9 formed by removing the sacrificial layer 9S communicates with the space outside the space 9, and this may reduce or prevent damage to the piezoelectric layer 2 due to the air pressure difference between the inside and the outside of the space 9.

The method for manufacturing the acoustic wave device 1C according to the third example embodiment further includes a through-plug forming step of forming the through-plug 21 in the through-hole 2H. As a result, the pressure difference between the space 9 and the second space 92 is reduce or prevented, thereby suppressing damage to the piezoelectric layer 2, while reducing or preventing damage to the piezoelectric layer 2 caused by the through-hole 2H.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
an acoustic wave element including a support including a support substrate having a thickness in a first direction, a piezoelectric layer laminated on the support and including a first main surface and a second main surface opposing the first main surface in the first direction, and a functional electrode on at least one of the first main surface and the second main surface of the piezoelectric layer; and
a package to house the acoustic wave element; wherein
the support includes a first space on a piezoelectric layer side at a position where the first space at least partially overlaps the functional electrode in a plan view in the first direction;
the package includes a second space outside the first space;
the piezoelectric layer includes a through-hole communicating with the first space and the second space; and
the first space, the second space, and outside of the package communicate with each other through at least one path.

2. An acoustic wave device, comprising:
an acoustic wave element including a support including a support substrate having a thickness in a first direction, a piezoelectric layer laminated on the support and including a first main surface and a second main surface opposite to the first main surface in the first direction, and a functional electrode on at least one of the first main surface and the second main surface of the piezoelectric layer; and
a package to house the acoustic wave element; wherein
the support includes a first space on a piezoelectric layer side at a position where the first space at least partially overlaps the functional electrode in a plan view in the first direction;
the package includes a second space outside the first space, the piezoelectric layer includes a through-hole communicating with the first space and the second space; and
the first space, the second space, and outside of the package have a same or substantially a same air pressure.

3. The acoustic wave device according to claim 1, wherein the package is at least partially made of a breathable resin.

4. An acoustic wave device, comprising:
a support including a support substrate having a thickness in a first direction;
a piezoelectric layer laminated on the support portion and including a first main surface and a second main surface opposite to the first main surface in the first direction;
a functional electrode on at least one of the first main surface and the second main surface of the piezoelectric layer;
a support frame on the piezoelectric layer in the first direction; and
a cover on the support frame in the first direction; wherein
the support includes a first space on a piezoelectric layer side at a position where the first space at least partially overlaps the functional electrode in a plan view in the first direction;
the support frame includes a second space;
the piezoelectric layer includes a through-hole through which the first space and the second space communicate with each other; and
the first space, the second space, and the outside of the cover communicate with each other through at least one path.

5. An acoustic wave device, comprising:
a support including a support substrate having a thickness in a first direction;
a piezoelectric layer laminated on the support portion and including a first main surface and a second main surface opposite to the first main surface in the first direction;
a functional electrode on at least one of the first main surface and the second main surface of the piezoelectric layer;
a support frame on the piezoelectric layer in the first direction; and
a cover on the support frame in the first direction; wherein
the support includes a first space on a piezoelectric layer side at a position where the first space at least partially overlaps the functional electrode in a plan view in the first direction;
the support frame includes a second space;
the piezoelectric layer includes a through-hole through which the first space and the second space communicate with each other; and
the first space, the second space, and outside of the cover have a same air pressure.

6. The acoustic wave device according to claim 4, wherein at least one of the support frame and the cover is at least partially made of a breathable resin.

7. The acoustic wave device according to claim 1, further comprising:
a through-plug in the through-hole and passing through the piezoelectric layer; wherein
the through-plug is breathable.

8. The acoustic wave device according to claim 7, wherein the through-plug includes a photosensitive polyimide resin.

9. The acoustic wave device according to claim 1, wherein the functional electrode is an interdigital transducer (IDT) electrode.

10. The acoustic wave device according to claim 1, wherein
the functional electrode includes a plurality of first electrode fingers extending in a second direction intersecting the first direction, a first busbar electrode to which the plurality of first electrode fingers are coupled, a plurality of second electrode fingers each opposing a corresponding one of the plurality of first electrode fingers in a third direction orthogonal to the second direction and extending in the second direction, and a second busbar electrode to which the plurality of second electrode fingers are coupled; and
when p represents a center-to-center distance between the first electrode finger and the second electrode finger adjacent to each other, among the plurality of first electrode fingers and the plurality of second electrode fingers, a thickness of the piezoelectric layer is about 2p or less.

11. The acoustic wave device according to claim 1, wherein the piezoelectric layer includes lithium niobate or lithium tantalate.

12. The acoustic wave device according to claim 1, wherein the acoustic wave device is structured to generate a plate wave.

13. The acoustic wave device according to claim 1, wherein the acoustic wave device is structured to generate a bulk wave in a thickness-shear mode.

14. The acoustic wave device according to claim 1, wherein
the functional electrode includes a plurality of first electrode fingers extending in a second direction intersecting the first direction, a first busbar electrode to which the plurality of first electrode fingers are coupled, a plurality of second electrode fingers each opposing corresponding one of the plurality of first electrode fingers in a third direction orthogonal to the second direction and extending in the second direction, and a second busbar electrode to which the plurality of second electrode fingers are coupled; and
d/p is about 0.5 or less, where d represents the thickness of the piezoelectric layer and p represents a center-to-center distance between the first electrode finger and the second electrode finger adjacent to each other.

15. The acoustic wave device according to claim 14, wherein d/p is 0.24 or less.

16. The acoustic wave device according to claim 1, wherein
the functional electrode includes a plurality of first electrode fingers extending in a second direction intersecting the first direction, a first busbar electrode to which the plurality of first electrode fingers are coupled, a plurality of second electrode fingers each opposing corresponding one of the plurality of first electrode fingers in a third direction orthogonal to the second direction and extending in the second direction, and a second busbar electrode to which the plurality of second electrode fingers are coupled; and
a metallization ratio MR satisfies MR≤about 1.75 (d/p)+0.075, where MR is a ratio of an area of the first electrode finger and the second electrode finger in an excitation region to the excitation region where the first electrode finger and the second electrode finger are overlapping each other when viewed in a direction in which the first electrode finger and the second electrode finger oppose each other.

17. The acoustic wave device according to claim 1, wherein
the piezoelectric layer is made of lithium niobate or lithium tantalate, and Euler angles (φ, θ, ψ) of lithium niobate or lithium tantalate constituting the piezoelectric layer are in a range of formula (1), formula (2), or formula (3):
$$\\ \begin{matrix}( 0 ° \pm 10 ° , 0 ° to 20 ° , any ψ ) ; & Formula ( 1 )\end{matrix}$$
$$\\ \begin{matrix}( 0 ° \pm 10 ° , 20 ° to 80 ° , 0 ° to 60 ° {( 1 - {( θ - 50 )}^{2} / 900 )}^{1 / 2} ) or & Formula ( 2 )\end{matrix}$$
$$\\ ( 0 ° \pm 10 ° , 20 ° to 80 ° , [ 180 ° - 60 ° {( 1 - {( θ - 50 )}^{2} / 900 )}^{1 / 2} ] to 180 ° ) ; and$$
$$\\ \begin{matrix}( 0 ° \pm 10 ° , [ 180 ° - 30 {° ( 1 - {( ψ - 90 )}^{2} / 8100 )}^{1 / 2} ] to 180 ° , any ψ ) & Formula ( 3 )\end{matrix}$$

18. A method for manufacturing an acoustic wave device, the method comprising:
forming a sacrificial layer on a portion of one of a pair of main surfaces of a piezoelectric layer including the pair of main surfaces opposite to each other in a thickness direction;
forming an intermediate layer on the one main surface of the piezoelectric layer and the sacrificial layer;
bonding the piezoelectric layer to a support substrate with the intermediate layer interposed therebetween;
forming an electrode on at least one of the pair of main surfaces of the piezoelectric layer;
forming a through-hole in the piezoelectric layer; and
removing the sacrificial layer.

19. A method for manufacturing an acoustic wave device, the method comprising:
forming step of forming an intermediate layer on a support substrate;
forming a piezoelectric layer on the intermediate layer;
forming an electrode on the piezoelectric layer;
forming a through-hole in the piezoelectric layer and the intermediate layer;
forming a space in a portion of the support substrate; and
etching the intermediate layer exposed to the space.

20. The method for manufacturing an acoustic wave device according to claim 18, further comprising:
filling the through-hole with a filler;
forming a support frame on the piezoelectric layer; and
etching the filler.

21. The method for manufacturing an acoustic wave device according to claim 20, wherein the filler includes a non-photosensitive resin.

22. The method for manufacturing an acoustic wave device according to claim 18, further comprising forming a through-plug in the through-hole.
